(19) United States
(12) Patent Application Publication
(10) Pub. No.: US 2025/0363278 A1
(43) Pub. Date: Nov. 27, 2025

(54) CONTROL APPARATUS, COMPUTER-IMPLEMENTED CONTROL METHOD, AND DISTRIBUTED PROCESSING SYSTEM

(71) Applicant: Fujitsu Limited, Kawasaki-shi (JP)

(72) Inventors: Hiroyoshi KODAMA, Isehara (JP); Makoto MAKINO, Kawasaki (JP); Takahide YOSHIKAWA, Kawasaki (JP)

(73) Assignee: Fujitsu Limited, Kawasaki-shi (JP)

(21) Appl. No.: 19/192,475

(22) Filed: Apr. 29, 2025

(30) Foreign Application Priority Data
May 27, 2024 (JP) 2024-085679

(51) Int. Cl. G06F 30/343

(52) U.S. Cl. CPC G06F 30/343

(57) ABSTRACT

A control apparatus includes a memory, and a processor coupled to the memory. The processor is configured to execute a process including reading, when information about a first process executed by a first circuit logic corresponding to a first template satisfies a given condition, a second template for a second circuit logic that executes a second process related to the first process from a storage area to obtain a read second template, the first circuit logic being set in a rewritable circuit area provided in a programmable logic circuit, the first circuit logic being implemented by writing the first template of which a circuit design synthesis has been completed and of which placement and routing have been already determined, into the circuit area; and writing the read second template into the circuit area to set the second circuit logic that executes the second process in the circuit area.

### CROSS-REFERENCE TO RELATED APPLICATION

This application is based upon and claims the benefit of priority of the prior Japanese Patent application No. 2024-085679, filed on May 27, 2024, the entire contents of which are incorporated herein by reference.

### FIELD

The present disclosure relates to a control apparatus, a computer-implemented control method, and a distributed processing system.

### BACKGROUND

In recent years, the improvement in the performance of semiconductor devices such as Central Processing Units (CPUs) has slowed down, and the enhancement of computer performance through advancements in the performances of semiconductor devices is approaching the limit.

On the other hand, due to the development of Artificial Intelligence (AI), the Internet of Things (IoT), and other technologies, the volume of data to be processed has increased. Applications executed by computers are expected to perform tasks at higher processing speeds and in greater processing volumes than ever before.

One approach for accelerating the speeds of applications is the use of a system employing a domain-oriented architecture (hereinafter referred to as “domain-oriented system”). A domain-oriented architecture is an approach that enhances the performance and operability of servers by narrowing down the application domain to be adopted and optimizing hardware and software in accordance with the characteristics of that domain.

In domain-oriented systems, Application-Specific Integrated Circuits (ASICs), known as accelerators, specialized for certain computations in certain fields, are utilized. Since ASICs are manufactured as dedicated hardware, their use is restricted to certain applications. This means that applying domain-oriented systems is difficult in view of design and manufacturing costs unless an application is expected to be commercially viable.

To facilitate the application of domain-oriented systems to various applications, Field-Programmable Gate Arrays (FPGAs) have attracted attention as rewritable ASICs. An FPGA represents one example of a Programmable Logic Device (PLD). A PLD may also be referred to as a programmable logic circuit.

An FPGA includes a circuit area where circuit logics are written and has a reconfigurable function that allows a rewriting of circuit logics in the circuit area. A circuit logic is information indicating a structure of a logic circuit that causes the FPGA to execute a given process. Since various types of ASICs can be produced through the rewriting process of circuit logics in the circuit area, the use of FPGAs in domain-oriented systems enables a balance between design and manufacturing costs and performance.

For example, related art is disclosed in Japanese Laid-open Patent Publication No. 2012-014705.

### SUMMARY

According to an aspect of embodiment(s), a control apparatus includes: a memory; and a processor coupled to the memory, the processor being configured to execute a process including: reading, when information about a first process executed by a first circuit logic corresponding to a first template satisfies a given condition, a second template for a second circuit logic that executes a second process related to the first process from a storage area to obtain a read second template, the first circuit logic being set in a rewritable circuit area provided in a programmable logic circuit, the first circuit logic being implemented by writing the first template of which a circuit design synthesis has been completed and of which placement and routing have been already determined, into the circuit area; and writing the read second template into the circuit area to set the second circuit logic that executes the second process in the circuit area.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram illustrating a configuration of a system according to a comparative example;

FIG. 2 is a diagram for illustrating one example of steps in a writing process of a circuit logic into an FPGA;

FIG. 3 is a block diagram illustrating an example of a configuration of a system according to one embodiment;

FIG. 4 is a block diagram illustrating an example of a hardware configuration of the system according to one embodiment;

FIG. 5 is a block diagram illustrating an example of a configuration of the system across a plurality of locations;

FIG. 6 is a block diagram illustrating an example of a software configuration of an optimization apparatus and a shared pool storage according to one embodiment;

FIG. 7 is a diagram illustrating one example of determination condition management information;

FIG. 8 is a diagram illustrating one example of template management information;

FIG. 9 is a flowchart illustrating an example of a operation of the system according to one embodiment;

FIG. 10 is a diagram illustrating a change in processing results according to a first operation example;

FIG. 11 is a diagram illustrating template management information according to the first operation example;

FIG. 12 is a diagram illustrating updates to the template management information according to the first operation example;

FIG. 13 is a sequence diagram illustrating the first operation example of the system according to one embodiment;

FIG. 14 is a sequence diagram illustrating the first operation example of the system according to one embodiment;

FIG. 15 is a sequence diagram illustrating the first operation example of the system according to one embodiment;

FIG. 16 is a diagram illustrating a change of the processing results according to a second operation example;

FIG. 17 is a diagram illustrating template management information according to the second operation example;

FIG. 18 is a diagram illustrating updates to the template management information according to the second operation example;

FIG. 19 is a diagram illustrating updates to the template management information according to the second operation example; and

FIG. 20 is a sequence diagram. illustrating the second operation example of the system according to one embodiment.

### DESCRIPTION OF EMBODIMENT(S)

Here, in a domain-oriented system (distributed processing system) that causes a plurality of processes to be executed in a distributed manner across one or more FPGAs, a case is assumed, for example, where an imbalance of loads on a plurality of circuit logics executing processes arises, for example, the number of execution requests for Process A is high while the number of execution requests for Process B is low.

In such a case, while an FPGA in which a circuit logic for Process B has been written has extra processing resources, an FPGA in which a circuit logic for Process A has been written may experience congestion of processing A (waiting for execution) due to a shortage of processing resources. Such a decrease in processing efficiency (operational efficiency) of the FPGA may cause a delay of processing in a computer that has issued execution requests for Process A.

One conceivable approach to eliminate the load imbalance would be to write the circuit logic for Process A into a circuit area in one or more FPGAs by utilizing a reconfigurable function. However, a rewriting process of the circuit logic into the FPGA takes time. For example, synthesis and placement and routing, which are parts of the rewriting process, may take several days. Hence, it is difficult to change processes to be executed by FPGAs in real time, and the elimination of the load imbalance may be difficult.

As described above, the processing efficiencies of FPGAs may be decreased depending on the loads on circuit logics in the FPGAs executing the processes, leading to processing delays in the computer that has issued the execution requests.

Hereinafter, an embodiment of the present disclosure will be described with reference to the drawings. However, the embodiment described below is merely exemplary, and it is not intended to exclude various modifications or applications of the techniques not explicitly described in the following. For example, various modifications can be made without departing from the scope thereof. In the drawings used in the following description, elements denoted by the like reference symbols denote the same or similar elements, unless otherwise stated.

### (A) Comparative Example

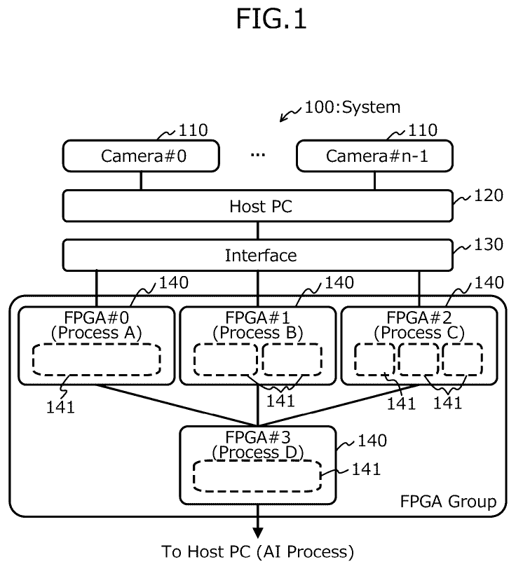

FIG. 1 is a block diagram illustrating a configuration of a system 100 according to a comparative example. The system 100 includes, as an example, a plurality of (n in the example in FIG. 1, where n is an integer of 2 or more) cameras 110 (cameras #0 to #n-1), a host Personal Computer (PC) 120, an interface 130, and one or more (four in the example in FIG. 1) FPGAs 140 (FPGA group).

The host PC 120 executes an AI process used in an autonomous driving or security system, etc. using captured images obtained by the plurality of cameras 110. The AI process may be, for example, an image recognition process such as an object detection process. In place of the captured images per se, images subjected to pre-processes (image processes), such as an edge extraction process or a binarization process, are input to the AI process.

The pre-processes are processes that impose high execution loads on the host PC 120. Therefore, when the host PC 120 executes the pre-processes, processing delays may arise. To address the processing delays, the system 100 according to the comparative example offloads an execution of the pre-processes from the host PC 120 to the FPGAs 140.

For example, the host PC 120 outputs the captured images to the FPGAs 140 via the interface 130 or a high-speed communication channel connected to Input/Output (I/O) ports (not illustrated) of the FPGAs 140. The host PC 120 then obtains a pre-processing result executed at high speed by the FPGAs 140 and performs the AI process using the pre-processing result.

Each FPGA 140 includes a circuit area in which a circuit logic can be rewritten such that a given process is executed by a circuit set in the circuit area. Hereinafter, when the FPGAs 140 are distinguished from each other, they are denoted as the FPGA #0 to the FPGA #3 (see FIG. 1). For example, the FPGA #0 to the FPGA #3 may perform the following respective processes.
FPGA #0: Process A—Edge extraction process for the captured images with 4K resolution
FPGA #1: Process B—Edge extraction process for the captured images with Full High Definition (FHD) resolution
FPGA #2: Process C—Edge extraction process for the captured images with Standard (STD) resolution
FPGA #3: Process D—Binarization process

In the example in FIG. 1, the captured images are inputted to one of the FPGA #0 to the FPGA #2 according to the resolutions. Edges extracted from the captured images by the FPGA #0 to the FPGA #2 (Processes A to C) are inputted to the FPGA #3, where binarization is performed by the FPGA #3 (Process D). The binarized image data is outputted to the host PC 120 as the pre-processing result.

Although Process A to Process C are all edge extraction processes for the captured images, the resolutions (maximum resolutions) that Process A to Process C can handle differ from each other. Since the same edge extraction process is made to be executed on one of the FPGA #0 to the FPGA #2 according to the resolutions in the example in FIG. 1, the configuration of the system 100 tends to be redundant.

Furthermore, Scales of the circuit set in the rewritable circuit areas in the FPGAs 140 vary depending on the contents of Process A to Process D executed by the circuits. In FIG. 1, the circuit scales for Process A to Process D are represented by sizes of the rectangles denoted by a reference symbols 141.

For example, the circuit scales 141 of the edge extraction processes, i.e., Process A to Process C, are increased as the resolution increases. In the example in FIG. 1, the order of the resolutions that can be handled by the processes from highest to lowest is as follows: Process A (4K), Process B (FHD), and Process C (STD). The order of the circuit scales 141 from largest to smallest is as follows: Process A, Process B, and Process C. It should be noted that Process D is a process that uses the pre-processing result sequentially outputted from Process A to Process C. Since Process D receives the edges based on the captured images with the resolution of 4K at maximum, the circuit scale 141 of Process D has the same circuit scale as that of Process A.

For the above reason, when the circuit in each FPGA 140 is changed using the reconfigurable function, for example, it is important to determine an appropriate combination of processes based on a size of a free area in the rewritable circuit area in each FPGA 140 and the circuit scale 141 of each process.

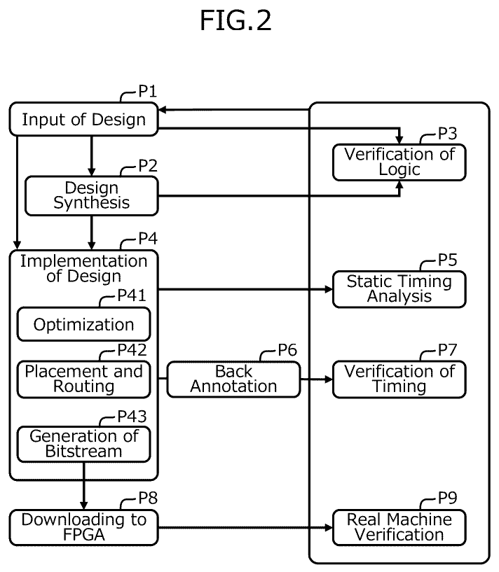

Next, a rewriting (writing) process of the circuit logic into the FPGA 140, in other words, a circuit setting process, will be described. FIG. 2 is a diagram for illustrating one example of steps in the writing process of the circuit logic into the FPGA 140.

As illustrated in FIG. 2, a developer inputs a design of the circuit logic into a development environment by using a language such as a Hardware Description Language (HDL)

(Process P1) and performs design synthesis using a logic synthesis tool (Process P2). At this time, the developer verifies the design by performing verification of the logic of the design (Process P3) to complete the design synthesis.

After the design synthesis is completed, the developer implements the design to incorporate the logic circuit into an FPGA 140 (Process P4).

For example, the developer performs optimization of each function to be implemented in the rewritable circuit area (Process P41) and then places and routes (Process P42) each of the optimized functions onto the circuit area. At this time, the developer performs a static timing analysis (Process P5) and back-annotation (Process P6) to verify timing (Process P7) to determine the placement and routing.

Thereafter, based on the determined placement and routing, the developer generates a bitstream for the circuit to be written (programmed) into the circuit area (Process P43).

The developer downloads the bitstream to the FPGA 140 (Process P8). For example, the developer writes the bitstream into an external storage device of the FPGA 140 via an interface compliant with a standard such as the Joint Test Action Group (JTAG) standard. Process P8 may also be referred to as a configuration of the FPGA 140 or the writing of the logic circuit.

The bitstream written to the external storage device is read from the external storage device at startup of the FPGA 140 or when the reconfigurable function is performed, and is written into the rewritable circuit area in the FPGA 140. After the bitstream is written into the circuit area, the developer performs a real machine verification (Process P9). Through this step, the setting of the circuit to the FPGA 140 is completed.

If an imbalance of the loads on the circuit logics executing Process A to Process D in the FPGAs 140 arises, for example, operational efficiencies of the FPGAs 140 are reduced, which may cause a delay in the execution of an AI process by the host PC 120. One conceivable approach to eliminate such an imbalance is to set a circuit executing a high-load process, to the circuit area in the FPGA 140 to which a circuit executing a low-load process has been set, thereby attempting to eliminate the load imbalance.

However, as described above, the synthesis and placement and routing (for example, Process P2 and Process P42 in FIG. 2), which are parts of the rewriting process, may take several days. Hence, it is difficult to change the process to be executed by the FPGAs 140 in real time.

Accordingly, in one embodiment, one example of a technique for improving the processing efficiency of FPGAs will be described.

### [B] Description of System According to One Embodiment

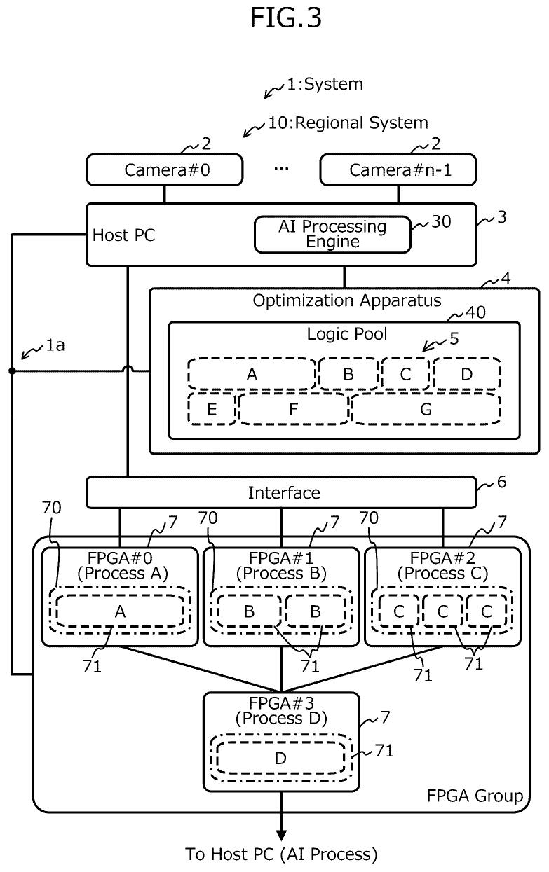

FIG. 3 is a block diagram illustrating an example of a configuration of a system 1 according to one embodiment. The system 1 represents one example of a distributed processing system or an information processing system. The system 1 includes a regional system 10. The regional system 10 represents one example of an information processing system provided in each region (each site). The regional system 10, as an example, includes a plurality of (n in the example in FIG. 3) cameras 2 (camera #0 to camera #n-1), a host PC 3, an optimization apparatus 4, an interface 6, and one or more (four in the example in FIG. 3) FPGAs 7 (FPGA group).

The system 1 according to one embodiment causes the FPGAs 7 to execute a plurality of processes that are pre-processes for an AI process. The pre-processes each represent one example of a first process or a second process and may include, for example, an edge extraction process for images and a binarization process based on the extracted edges. It should be noted that the plurality of processes executed by the FPGAs 7 are not limited to the pre-processes for the AI process and may include various processes.

The cameras 2 each represent one example of an image capturing device that captures a given imaging area and outputs a captured image. Each of the plurality of cameras 2 may output the captured image with different resolutions.

The host PC 3 represents one example of an information processing apparatus or a computer and includes an AI processing engine 30 that performs the AI process on the captured images obtained by the cameras 2. The AI processing engine 30 represents one example of a machine learning model. The host PC 3, for example, offloads the pre-process to the FPGA 7 and performs the AI process using the AI processing engine 30 based on the pre-processing result from the FPGA 7.

For example, when the host PC 3 obtains the captured image from the camera 2, the host PC 3 may send an execution request (processing request) for the pre-process including the obtained captured image. The execution request may be sent in such a manner that the optimization apparatus 4 can obtain the execution request. The AI process may be, for example, an image recognition process such as an object detection process and may be used in an autonomous driving or security system, etc.

It should be noted that the host PC 3 and the optimization apparatus 4 may be communicably connected to I/O ports of the FPGAs 7 via a communication path 1a. The communication path 1a may be used for processing such as transmissions of the execution requests for the pre-processes and the pre-processing result, as well as the writing of templates 5 into circuit areas 70. For example, the host PC 3 may send the execution request to the optimization apparatus 4 via a network or the communication path 1a. Additionally, the host PC 3 may receive the pre-processing result from the FPGAs 7 via the interface 6.

Each FPGA 7 represents one example of a PLD, and may include the rewritable circuit area 70 and execute a given process using a logic circuit set in the circuit area 70. Hereinafter, when the FPGAs 7 are distinguished from each other, the FPGAs 7 are denoted as FPGA #0 to #3 (see FIG. 3). For example, the FPGA #0 to #3 may execute above-described Process A to Process D, respectively. In FIG. 3, the circuit scales of respective processes are represented by corresponding rectangles denoted by reference symbols 71.

The optimization apparatus 4 represents one example of a control apparatus, an information processing apparatus, or a computer, and serves as an optimizer that enhances the processing efficiencies of the FPGAs 7. The optimization apparatus 4 may be, for example, provided between the host PC 3 and the FPGAs 7 such that the optimization apparatus 4 can communicate with both the host PC 3 and the FPGAs 7.

For example, the optimization apparatus 4 may include a logic pool 40. The logic pool 40 represents one example of a storage area and may store a plurality of templates 5 for which circuit design synthesis is completed and placement and routing are determined. The templates 5 are information to be written into the circuit areas 70 to thereby implement circuit logics and may be, as one example, bitstreams.

When the optimization apparatus 4 detects a load imbalance among the circuit logics set in the rewritable circuit areas 70 of one or more FPGAs 7 that execute a plurality of processes, the optimization apparatus 4 reads a first template 5 that satisfies a given condition from the logic pool 40. The first template 5 may be, for example, a template 5 for a circuit that executes a high-load process (as one example, a process that is stalled).

The optimization apparatus 4 writes the first template 5 that is read into a first circuit area 70 from among one or more circuit areas 70 that satisfies a condition. Thereby, the optimization apparatus 4 sets a first circuit logic that is implemented by the first template 5 and executes the first process, in the first circuit area 70.

In recent years, the FPGAs 7 have various functions such as I/O and networking integrated therein, in addition to dedicated functions. Rewriting of only a part of the dedicated function of the FPGA 7 can be done in a few milliseconds once the logic circuit to be rewritten has been prepared, making the FPGAs 7 highly versatile.

In view of this point, in one embodiment, the templates 5 for circuits that can be set in the FPGAs 7 are prepared in advance. This allows the optimization apparatus 4 to set the logic circuit in the circuit area 70 to thereby eliminate the load imbalance between the circuit logics in real time or near real time. As a result, processes executed by the FPGAs 7 are optimized, thereby improving the processing efficiencies of the FPGAs 7.

If a processing result of the first process executed by the first circuit logic implemented by the first template 5 satisfies a detection condition, the optimization apparatus 4 according to one embodiment reads a second template 5 for a second circuit logic that executes a second process, from the logic pool 40. The detection condition represents one example of a given condition. The first process and the second process may be pre-processes, for example, and may be referred to as a first pre-process and a second pre-process, respectively. The second process is a process related to the first process.

The second template 5 that is read may be, for example, a template 5 for a circuit that executes the second process partially different from the first process. Alternatively, the second template 5 that is read may be a template 5 for a circuit that executes a second process that is the same process as the first process but has a greater processing volume than that of the first process (as one example, a template 5 having the same size as the logical partition size).

The optimization apparatus 4 writes the second template 5 that is read into the circuit area 70 to thereby set the second circuit logic that executes the second pre-process in the circuit area 70. The first template 5 has been written in the circuit area 70 before the second template 5 is written. Therefore, the process of “writing” the second template 5 is a process for overwriting the template 5 and can be considered as a rewriting process of the template 5.

With the above-described configuration, if it is determined that the detection condition is satisfied, the optimization apparatus 4 executes the replacement of the template 5 in the circuit area 70 without requiring user's operations. This allows an appropriate circuit logic to be set in a circuit area 70, thereby efficiently restoring the performance of the pre-process performed by the circuit logic or a process that utilizes the pre-processing result, for example.

In other words, the optimization apparatus 4 can set the logic circuit in the circuit area 70 in real time or near real time to improve or maintain the processing performance. Therefore, in the above-described configuration that improves the processing efficiencies of the FPGAs 7 by optimizing processes executed by the FPGAs 7, it is possible to suppress the reduction in performance of pre-processes executed by the FPGAs 7 or a process that utilizes the pre-processing result by the FPGAs 7.

### (C) Example of Hardware Configuration

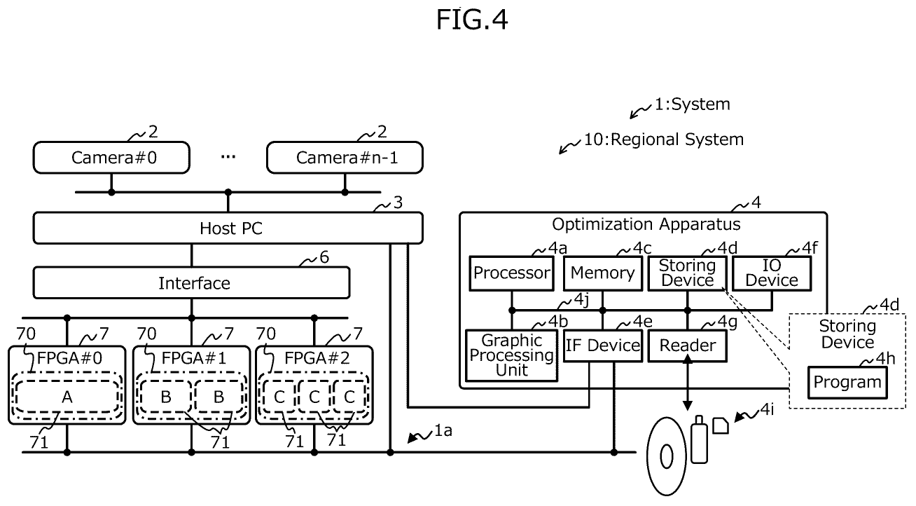

FIG. 4 is a block diagram illustrating an example of a hardware configuration of the system 1 according to one embodiment. FIG. 4 focuses on the configuration of the connection between devices in one regional system 10 in the system 1 illustrated in FIG. 3, and the configuration of the optimization apparatus 4.

As illustrated in FIG. 4, the cameras 2 and the host PC 3, as well as the host PC 3 and the optimization apparatus 4, may be communicably connected to each other via a network such as a Local Area Network (LAN) or the Internet.

Examples of the interface 6 include interconnects compliant with standards such as Peripheral Component Interconnect Express (PCIe) or Compute Express Link (CXL). For example, the interface 6 may be an adapter (connector) compliant with PCIe or CXL. Additionally, the interface 6 may include, in addition to the adapter, a PCIe switch or CXL switch that switches communications (connections) between the host PC 3 and each of the FPGAs 7.

Furthermore, as illustrated in FIG. 4, the host PC 3 and the FPGAs 7, as well as the optimization apparatus 4 and the FPGAs 7, may be communicably connected to each other via the high-speed communication path 1a compliant with the standard for the I/O ports of the FPGAs 7.

At least one of the host PC 3 and the optimization apparatus 4 according to one embodiment may be a physical server or a virtual server (Virtual Machine, VM). Additionally, at least either of the functions of the host PC 3 and the functions of the optimization apparatus 4 may be implemented by a single computer or by two or more computers.

The functions of the host PC 3 and the functions of the optimization apparatus 4 according to one embodiment may both be implemented by computers having similar hardware (HW) configurations. Hereinafter, the HW configurations of the host PC 3 and the optimization apparatus 4 will be described, with the optimization apparatus 4 taken as a representative example.

FIG. 4 illustrates an example where a single computer is used as the HW resource to implement the functions of the optimization apparatus 4. However, when a plurality of computers are used, each computer may have the HW configuration exemplified in FIG. 4.

As illustrated in FIG. 4, the optimization apparatus 4 may include, as an example, a processor 4a, a graphic processing unit 4b, a memory 4c, a storing device 4d, an interface (IF) device 4e, an IO device 4f, and a reader 4g, as the HW configuration.

The processor 4a represents one example of a processing device that performs various controls and operations. The processor 4a may be communicably connected to each block in the optimization apparatus 4 via a bus 4j. The processor 4a may be a multiprocessor having a plurality of processors, may be a multicore processor having a plurality of processor cores, or may be configured to have a plurality of multicore processors.

Examples of the processor 4a include Integrated Circuits (ICs), such as a CPU, MPU, APU, DSP, ASIC, or FPGA, for example. It should be noted that two or more combinations of these integrated circuits may be used for the processor 4a. MPU is an abbreviation for Micro Processing Unit. APU is an abbreviation for Accelerated Processing Unit. DSP is an abbreviation for Digital Signal Processor.

The graphic processing unit 4b controls screen displays to an output device such as a monitor, which is a part of the IO device 4f. Additionally, the graphic processing unit 4b may be configured as an accelerator that performs machine learning processes and inference processes using the machine learning models. Examples of the graphic processing unit 4b include various arithmetic processing units, such as Integrated Circuits (ICs), e.g., a Graphics Processing Unit (GPU), APU, DSP, ASIC, or FPGA.

The memory 4c represents one example of hardware for storing information, such as various data and programs. Examples of the memory 4c include either or both volatile memory, such as Dynamic Random Access Memory (DRAM), and non-volatile memory, such as Persistent Memory (PM), for example.

The storing device 4d represents one example of hardware for storing information, such as various data and programs. Examples of the storing device 4d include various storing devices such as magnetic disk devices, e.g., a Hard Disk Drive (HDD), semiconductor drive devices, e.g., an SSD, and non-volatile memory. Examples of non-volatile memory include flash memory, Storage Class Memory (SCM), and Read Only Memory (ROM), for example.

The storing device 4d may store a program 4h (control program) for embodying all or a part of the various functions of the optimization apparatus 4.

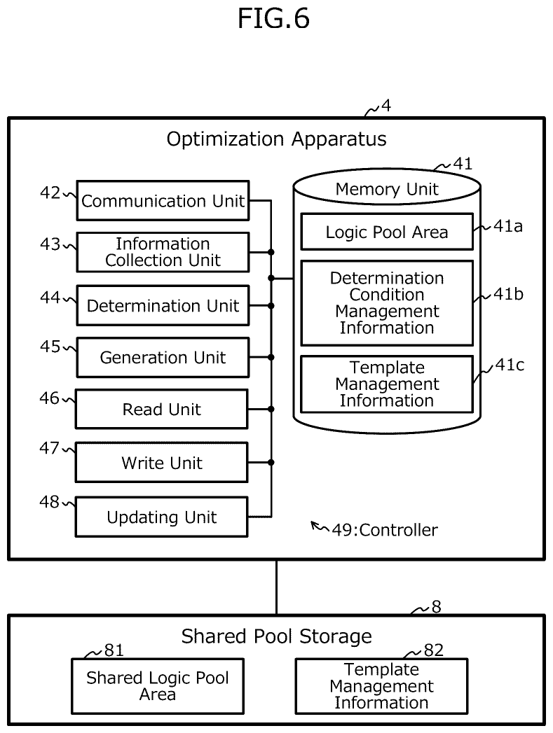

For example, the processor 4a of the optimization apparatus 4 may embody functions of the optimization apparatus 4 (for example, a controller 49 illustrated in FIG. 6) described later by loading the program 4h stored in the storing device 4d into the memory 4c and executing the program 4h.

The IF device 4e represents one example of a communication IF that performs controls, etc. on connections and communications between the host PC 3 and the optimization apparatus 4, as well as between the optimization apparatus 4 and the FPGAs 7. For example, the IF device 4e may include an adapter compliant with various communication standards such as Ethernet®, InfiniBand, Myrinet, PCIe, CXL, or the I/O ports of the FPGAs 7. This adapter may support either or both wireless and wired communication methods. The adapter may also be compliant with optical communications, such as Fibre Channel (FC).

It should be noted that the program 4h may be downloaded from a network, which is not illustrated, to the optimization apparatus 4 via the communication IF and stored in the storing device 4d.

The IO device 4f may include either or both an input device and an output device. Examples of the input device include a keyboard, a mouse, and a touch panel, for example. Examples of the output device include display devices, such as a monitor, a projector, and a printer, for example. Alternatively, the IO device 4f may include a touch panel that integrates an input device and an output device. The output device may be connected to the graphic processing unit 4b.

The reader 4g represents one example of a reader that reads information, such as data or a program recorded on a storage medium 41. The reader 4g may include a connection terminal or device to which the storage medium 4i can be connected or inserted. Examples of the reader 4g include adapters that are compliant with standards, such as Universal Serial Bus (USB), drive devices that access recording disks, and card readers that access flash memory, such as SD cards, for example. It should be noted that the program 4h may be stored in the storage medium 4i, and the reader 4g may read the program 4h from the storage medium 4i and store the program 4h in the storing device 4d.

Examples of the storage medium 4i include, as an example, non-transitory computer-readable storage media such as magnetic/optical disks and flash memory. Examples of the magnetic/optical disk include, as an example, flexible disks, Compact Discs (CDs), Digital Versatile Discs (DVDs), Blu-ray discs, and Holographic Versatile Discs (HVDs). Examples of the flash memory include semiconductor memory devices such as USB memory and SD cards.

The above-described hardware configuration of the optimization apparatus 4 is exemplary. Accordingly, hardware components may be added or deleted (any block may be added or deleted, for example), divided, integrated in any combination, or buses may be added or deleted, in the optimization apparatus 4, as appropriate. For example, devices, such as the I/O device 4f and the reader 4g, may be omitted from the optimization apparatus 4.

Additionally, the host PC 3 may have a HW configuration similar to that of the optimization apparatus 4. For example, the processor 4a in the host PC 3 loads the program 4h stored in a storing device 4d into the memory 4c and executes it, and performs controls such as instructions to the graphic processing unit 4b, thereby implementing the function of the host PC 3 (AI processing engine 30).

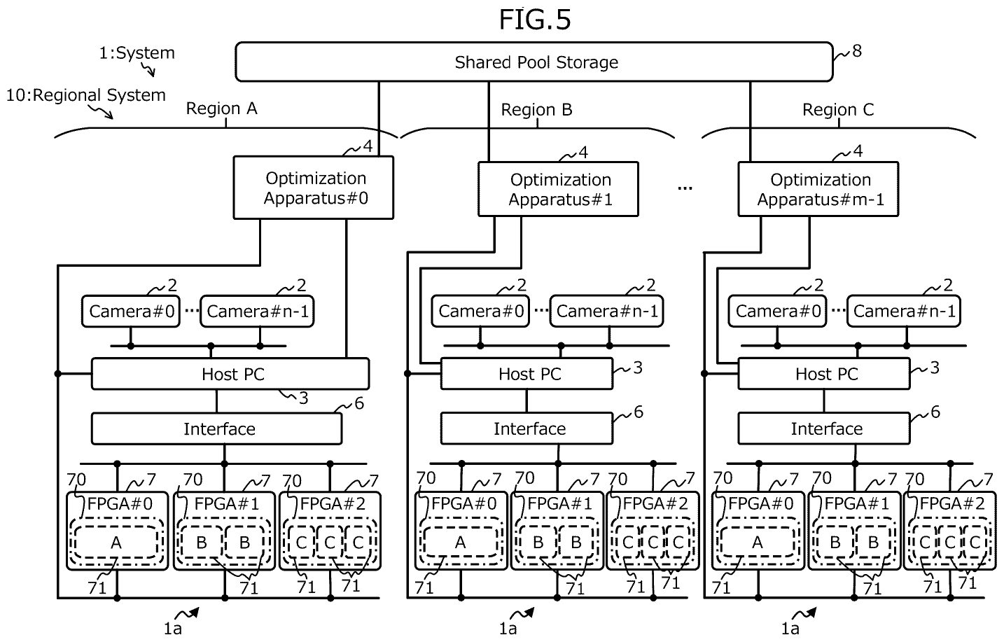

FIG. 5 is a block diagram illustrating an example of a configuration of the system 1 across a plurality of locations. As illustrated in FIG. 5, the system 1 may include a shared pool storage 8 and a plurality (m in the example in FIG. 5, where m is an integer of 2 or more) of the regional systems 10. It should be noted that the shared pool storage 8 and the optimization apparatuses 4 in the regional systems 10 may be communicably connected to each other via the IF devices 4e described above, for example, through a network such as a LAN or the Internet. The shared pool storage 8 may be accessible by each of the plurality of optimization apparatuses 4, and may be, as one example, a storage implemented in a cloud environment, such as cloud storage.

The shared pool storage 8 is a storage area shared among the plurality of logic pools 40, in other words, shared among the plurality of regional systems 10 (e.g., the plurality of optimization apparatuses 4), and represents one example of a shared storage area. The shared pool storage 8 may store a plurality of the templates 5. The shared pool storage 8 may include, for example, a processor, memory, interface, etc. illustrated), in addition to various storage devices t illustrated) capable of storing the plurality of templates 5.

The regional system 10 at each site shares the templates 5 in the shared pool storage 8. Therefore, even when the optimization apparatus 4 can no longer achieve optimal operations with the templates 5 present in the logic pool 40 in its own local site, the optimization apparatus 4 can use the templates 5 from the shared pool storage 8 to set the logic circuits.

One regional systems 10 exemplified in FIG. 5 may be provided at each region (one site), namely, Region A, Region B, . . . , or Region C.

Each regional system 10 may have the hardware configuration exemplified in FIG. 4. For example, each regional system 10 may include one or more cameras 2, the interface 6, one or more FPGAs 7, as well as the host PC 3 and the optimization apparatus 4 (optimization apparatuses #0 to m-1) to realize edge computing.

Since the configuration described above can reduce communication latency in each regional system 10 between the apparatuses constituting the regional system 10, relatively fast AI processes such as the image recognition process for autonomous driving and the pre-processes therefor can be achieved by the host PC 3 and the optimization apparatus 4.

### (D) Example of Software Configuration

FIG. 6 is a block diagram illustrating an example of a software configuration of the optimization apparatus 4 and the shared pool storage 8 according to one embodiment. As illustrated in FIG. 6, the optimization apparatus 4 may include, as one example, a memory unit 41, a communication unit 42, an information collection unit 43, a determination unit 44, a generation unit 45, a read unit 46, a write unit 47, and an updating unit 48. The communication unit 42, the information collection unit 43, the determination unit 44, the generation unit 45, the read unit 46, the write unit 47, and the updating unit 48 represent one example of a controller 49.

The memory unit 41 represents one example of a storage area, and stores various data used by the optimization apparatus 4. The memory unit 41 may be embodied, for example, by a storage area provided by either or both the memory 4c and the storing device 4d (see FIG. 4) in the optimization apparatus 4.

As illustrated in FIG. 6, the memory unit 41 may store, for example, a logic pool area 41a, determination condition management information 41b, and template management information 41c. The determination condition management information 41b represents one example of information for managing determination conditions. The template management information 41c represents one example of information for managing the templates 5.

The logic pool area 41a is a storage area allocated as the logic pool 40 (see FIG. 3). It should be noted that the storage area in the logic pool area 41a for storing the plurality of the templates 5 as the logic pool 40 may be embodied by the storage area in the storing device 4d. Furthermore, the storage area in the logic pool area 41a for storing the template 5 selected from the logic pool 40 (read from the storing device 4d) to be written into the FPGA 7 may be embodied by the storage area in the memory 4c.

The shared pool storage 8 may include, as an example, a shared logic pool area 81 and template management information 82. The shared logic pool area 81 is a storage area allocated as a logic pool in the shared pool storage 8. The template management information 82 represents one example of information for managing the templates 5 in the shared pool storage 8. The shared logic pool area 81 and the storage area for storing the template management information 82 may each be embodied by a storage area in either or both hardware similar to the memory 4c and hardware similar to the storing device 4d in the optimization apparatus 4.

Hereinafter, the templates 5 stored in the logic pool 40 will be described. Here, a case is assumed, for example, where the host PC 3 (AI processing engine 30) collects image data from the cameras 2 used in autonomous driving or the like and performs the AI process.

To compensate for differences in the performances of the plurality of the cameras 2 and differences in the captured images due to image-capturing environments such as day or night, the pre-process is performed on the captured images. The pre-process includes one or more processing elements, such as downsampling, brightness correction, perspective transformation, distortion correction, and edge extraction, for example. The number and contents of the processing elements vary depending on the content of the AI process.

These processes are executed according to the maximum resolution. Therefore, a processing pipeline is generated for each resolution, and processes are performed by the FPGA 7 for each processing pipeline. Examples of processes included in the processing pipeline, i.e., processes executed by the FPGA 7, include the following series of processes:
Processing pipeline: downsampling→brightness correction→distortion processing→edge extraction

The number of input images (the number of channels) that can be processed in a single processing pipeline decreases as the resolution increases. Examples of resolutions of the captured images inputted to a pre-process include in descending order: 8K (7680×4320), 4K (3840×2160), WQHD (2560×1440), FHD (1920×1080), WXGA++ (1600×900), and HD (1280×720), for example. The numbers in parentheses for each resolution indicate the number of pixels (horizontal direction x vertical direction).

Thus, the number of the processing pipelines increases as the resolution increases, and consequently, the circuit scale 71 of the logic circuit written into the circuit area 70 in an FPGA 7 is increased. For comparison of the circuit scales 71, FIG. 3 to FIG. 5 illustrate the processing pipelines (Process A to Process C) executed by the FPGA #0 to #2, where Process A is for 4K images, Process B is for WQHD images, and Process C is for FHD images.

Bitstreams (Process P43 in FIG. 2) generated through the synthesis (Process P2 in FIG. 2) and placement and routing (Process P42 in FIG. 2) for a plurality of processes including Process A to Process C may be stored in the logic pool 40 in advance. In FIG. 3, the templates 5 for the logic circuits that execute Process A to Process C are stored in the logic pool 40.

The communication unit 42 uses the IF device 4e (see FIG. 4) to perform various communications with each of the host PC 3 and the FPGAs 7.

The information collection unit 43 collects the processing result from each of the host PC 3 and the FPGAs 7 via the communication unit 42. The processing result represents one example of information about the first process. The information about the first process may include either or both an indicator (first information) indicating desirability of the result (inference result) obtained by inputting the result of the first process into the machine learning model, and information (second information) about the load on the circuit logic that executes the first process. The information collection unit 43 may collect a processing result, for example, every given time interval (for example, every 5 seconds).

An example of the first information may be, for example, the recognition rate when the image recognition process is executed by inputting the pre-processing result of the first process into the machine learning model. The information collection unit 43 may collect the recognition rate outputted from the AI processing engine 30 of the host PC 3 via a network.

An example of the second information may be, for example, an operating rate, which represents one example of information about the load on the circuit logic that executes the first process. The information collection unit 43 may obtain the operating rate based on an operation status of the FPGA 7.

An example of the operation status may be, for example, a network transfer volume of the FPGA 7. For example, the information collection unit 43 may use a system monitoring tool to obtain the network transfer volume of each FPGA 7 via the communication path 1a. It should be noted that the information collection unit 43 (and the determination unit 44 described later) may also obtain the network transfer volume by measuring the volume of information (data) sent to each FPGA 7.

Furthermore, according to the approach according to one embodiment, the logic circuit that performs two or more types of processes may be set in each FPGA 7. In such cases, the information collection unit 43 may obtain the network transfer volume for each process type (template 5) operating on the FPGA 7. The network transfer volume for each process type may be, for example, the network transfer volume for each logic circuit executing that process.

For example, the information collection unit 43 may calculate a ratio of the obtained (current) network transfer volume to the maximum network transfer volume when the FPGA 7 or each process operates with the maximum number of the input images (the maximum number of channels), as the operating rate of the FPGA 7 or the each process. The maximum network transfer volume may be measured in advance, for example. In this manner, by using the network transfer volume for the calculation of the operating rate, the information collection unit 43 can estimate the accurate load based on the actual operation status of the logic circuit. It should be noted that the operating rate of the FPGA 7 or each process can be considered to be the indicator indicating the processing volume by the FPGA 7 or the each process.

Furthermore, for example, the information collection unit 43 may obtain (receive) the execution request for the pre-process from the host PC 3. As an example, the information collection unit 43 may obtain the execution request sent from the host PC 3 through the communication path 1a, via the IF device 4e (communication IF). In cases where the host PC 3 can change how the execution request is sent, the host PC 3 may also send the execution request to the optimization apparatus 4 through a network such as a LAN. In this case, the information collection unit 43 may obtain the execution request through that network via the communication interface (the IF device 4e).

It should be noted that the information collection unit 43 may use the number of the execution requests received from the host PC 3 for calculating the operating rate of the FPGA 7. As an example, the information collection unit 43 may calculate the ratio of the number of the execution requests issued from the host PC 3 to the FPGA 7 within a given time period to the maximum number of the execution requests that the FPGA 7 can process within the given time period, as the operating rate of the FPGA 7.

The determination unit 44 determines whether or not the processing result obtained by the information collection unit 43 satisfies the detection condition. When the determination unit 44 determines that the processing result satisfies the detection condition, the determination unit 44 determines that the second template 5 is to be written into the circuit area 70 where the first circuit logic for the first pre-process has been written.

The detection condition may include, for example, either or both a first condition that the recognition rate is less than a first given value, and a second condition that the load is equal to or greater than a second given value.

For example, if the determination unit 44 determines that the recognition rate is less than the first given value based on the recognition rate of the AI process by the host PC 3, the determination unit 44 may determine that the second template 5 matching a read condition in the determination condition described later is to be set to a given circuit area 70.

Additionally or alternatively, if the determination unit 44 determines that the operating rate of the first circuit logic that executes the first pre-process is equal to or greater than the second given value, the determination unit 44 may determine that the second template 5 matching the read condition in the determination condition described later is to be set to the given circuit area 70.

The determination condition refers to a condition that is compliant with a policy in which the state indicated by the processing result, in other words, the state indicated by a monitoring result of the recognition rate and operating rate, is matched, from among a plurality of policies. Hereafter, the processing result may sometimes be referred to as the monitoring result.

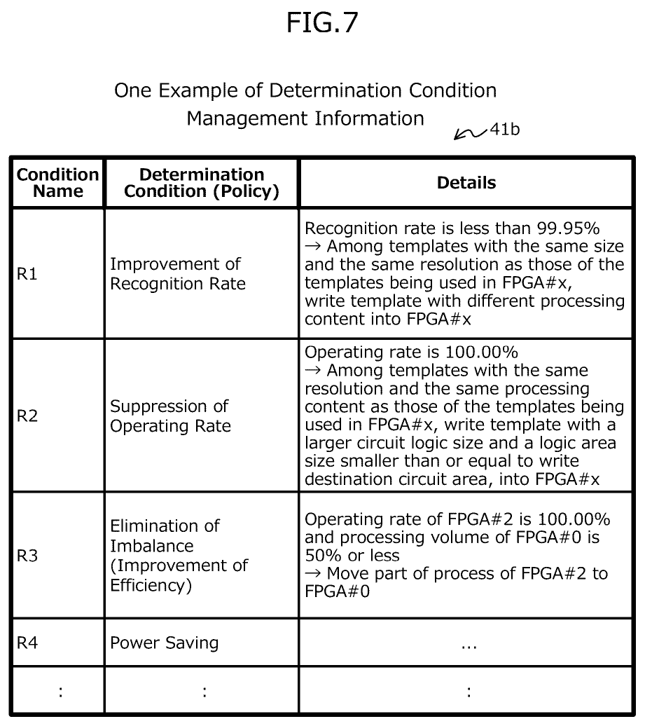

FIG. 7 is a diagram illustrating one example of the determination condition management information 41b. As illustrated in FIG. 7, the determination condition management information 41b include the items “Condition Name”, “Determination Condition (Policy)”, and “Details”.

The “Condition Name” represents one example of identification information for the entries of the determination conditions. The “Determination Condition (Policy)” has various approaches for resolving the imbalance of processes, such as approaches (perspectives) including “Improvement of Recognition Rate”, “Suppression of Operating Rate”, and “Improvement of Efficiency”, for example. The “Details” has concrete conditions for achieving the approach for the determination condition, and may define at least one of the detection condition, the information of the template 5 to be written (read condition), and the information of the FPGA 7 where the template 5 is to be written (write condition). Examples of the detection condition includes, for example, conditions such as low recognition rate, high operating rate, or imbalance state. The FPGA #x illustrated in FIG. 7 is the FPGA 7 where the written template 5 (circuit logic) satisfies the detection condition. In the examples in FIG. 3 to FIG. 5, 0≤x≤2.

The determination unit 44 compares the processing result with the determination condition management information 41b and, if the monitoring result matches the detection condition, determines that the template 5 matching the read condition of that entry is to be written to the FPGA 7 matching the write condition. The template 5 matching the read condition represents one example of the second template 5 for the second circuit logic that executes the second process related to the first process. Then, the determination unit 44 notifies the read unit 46 and the write unit 47 of the determination result.

Hereinafter, one example of the determination process by the determination unit 44 will be described. A case is assumed where the recognition rate of the AI process using the pre-processing result of Process A executed by the FPGA #0 is less than 99.95%. Process A represents one example of the first process. In the above-described determination condition, the detection condition “Recognition rate is less than 99.95%” represents one example of the first condition.

In this case, the determination unit 44, based on the entry (condition name) R1 in the determination condition management information 41b, determines that the second template 5 that has the same resolution (in this case, the 4K processing) as the resolution of Process A and executes a second pre-process is to be written into the FPGA #0. The second pre-process may be a pre-process that includes one or more processing elements to which at least one of deletion of one or more processing elements, replacement of one or more processing elements, and addition of one or more processing elements, among a plurality of processing elements included in the first pre-process, have been applied. This allows for automatic rewriting of the template 5 when a decrease in recognition rate is detected, thus efficiently suppressing the decrease in recognition rate, for example, to thereby recover (improve) the recognition rate, without the need for user's operations to add a template 5 to the logic pool 40.

Another example of the determination process by the determination unit 44 will be described. A case is assumed where the operating rate of the FPGA #2 that executes Process C is 100.00%. Process C represents one example of the first process. In the above-described determination condition, the detection condition “Operational rate is 100.00%” represents one example of the second condition for determining whether the processing load on the first circuit logic by the first template 5 that has been written is equal to or greater than a second given value (e.g., 100.00%). The given value may also be less than 100.00%.

In this case, the determination unit 44, based the determination condition R2 in the determination condition management information 41b, determines that second template 5 that executes a second pre-process that has the same resolution as the resolution of Process C (in this case, the FHD processing) and includes the same processing elements as those included in Process C, is to be written into the FPGA #2. At this time, the determination unit 44 determines that the template 5 that has a logical partition size larger than that of the template 5 for executing Process C and equal to or smaller than the circuit scale 71 of the FPGA #2 is to be written, as the second template 5 for executing the second pre-process. This allows the size of the circuit logic (circuit scale 71) that executes Process C to be expanded, for example, the number of processing pipelines for executing parallel processing to be increased. As a result, the throughput of the circuit logic that executes Process C in the FPGA #2 can be improved, and the operating rate can be reduced.

Here, a conceivable operation might be one where the user adds the template 5 to the logic pool 40 based on the processing result through user's operations, and the optimization apparatus 4 writes the added template 5 to the FPGA 7, for example. In such a case, however, it is unclear whether the optimization of the system 1 is achieved with the added template 5 alone. On the other hand, the determination unit 44 according to one embodiment repeats the process of determining that the second template 5 for executing the second pre-process is to be written to the FPGA 7 and selecting the template 5 that satisfies the read condition from the template management information 41c, until the processing result no longer satisfies the detection condition. This allows for a more efficient setting of the optimal template 5 compared to the case where the template 5 is added through user's operations.

If there are multiple entries where the detection condition matches the processing result in the determination condition management information 41b, the determination unit 44 may select the policy with the highest priority according to the priority of the policies. Examples of the priority of the policies (in descending order) include, for example, the descending order of entries (condition names), the descending order of strictness of the detection condition (higher number of conditions, higher recognition rate, lower operating rate, etc.), or priority set in advance by the administrator.

The determination unit 44 may be embodied, for example, by a function of an application such as an optimization solver or by a machine learning model trained by an approach such as Deep Learning. The machine learning model may be trained to, in response to an input of the monitoring result, for example, output the condition for the read operation and the condition for the write destination according to the detection condition.

It should be noted that the determination unit 44 may identify the templates 5 to be written initially to each FPGA 7 when the system 1 (or the FPGA 7) is started, and notify the read unit 46 and the write unit 47 of the templates 5. The initial template 5 to be written may be specified by the administrator or user of the system 1, or the determination condition for selecting the initial template 5 may be set in the determination condition management information 41b.

Furthermore, the determination unit 44 refers to the template management information 41c and selects an appropriate FPGA 7 that processes the execution request sent from the host PC 3 as the forwarding destination FPGA 7 of the execution request.

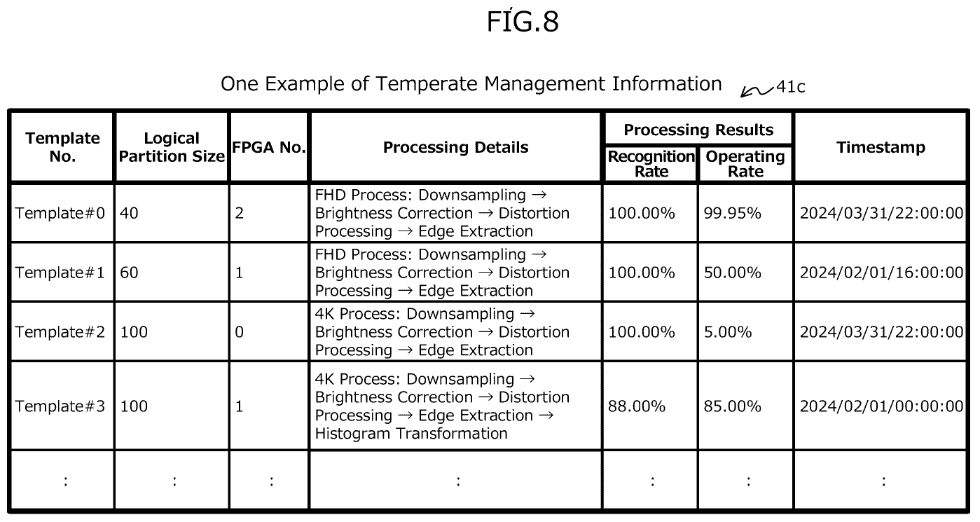

FIG. 8 is a diagram illustrating one example of the template management information 41c. As illustrated in FIG. 8, the template management information 41c may include the items “Template No.”, “Logical Partition Size”, “FPGA No.”, “Processing Details”, “Processing Results”, and “Timestamp”.

The “Template No.” represents one example of identification information for the template 5. The “Logical Partition Size” is the area size occupied in the circuit area 70 (logical partition) by the logic circuit implemented by the template 5, and represents one example of the circuit scale 71. The “FPGA No.” represents one example of identification information for the FPGA 7.

The “Processing Details” is the details of the processing implemented by the circuit logic implemented by the template 5, as the logic circuit. For example, the template #2 illustrated in FIG. 8 is the template 5 for the logic circuit implementing the 4K processing (having a size of 100).

The “Processing Results” represents one example of information about the pre-processing. In the example in FIG. 8, the “Processing Results” include “Recognition Rate” and “Operating Rate”, which are the elements of the detection condition (see FIG. 7). The “Recognition Rate” is the recognition rate by the AI process using the pre-processing result of the template 5. The “Operating Rate” is the operating rate of the circuit logic that executes the pre-process according to the template 5. The “Timestamp” represents one example of information about the latest use of the template 5, and the time when the template 5 was last written to the circuit area 70 in the FPGA 7 may be set, for example.

For example, the determination unit 44 may identify the template 5 that implements the process requested in the execution request sent from the host PC 3 from the template management information 41c, and may identify the FPGA 7 operating the identified template 5 from the template management information 41c. The determination unit 44 then may issue (send) the execution request sent from the host PC 3 to the identified FPGA 7 via the communication path 1a. This allows the load of each type of template 5 (logic circuit) to be distributed, and thus improves the processing efficiency of the system 1 as a distributed processing system.

When the same template 5 is set in multiple logical partitions in one FPGA 7 or in multiple FPGAs 7, the process of the template 5 can be executed in each of these multiple logical partitions. If the determination unit 44 identifies multiple FPGAs 7 (logical partitions) as destination candidates for issuing the obtained execution request, the determination unit 44 may determine the destination to issue the execution request based on the processing loads on the circuit logics of the FPGAs 7 (logical partitions).

For example, the determination unit 44 may use a part of the storage area in the memory 4c in the optimization apparatus 4 as a queue (buffer) for storing execution requests. The queue may be shared for all execution requests, or one queue may be provided for each template 5 or each FPGA 7. For example, the determination unit 44 may read the execution request queued in the queue using a logic such as First-In First-Out (FIFO) and issue the execution request to the FPGA 7 (logical partition) selected from the destination candidates. The pre-processing result by the FPGA 7 is sent to the host PC 3 via the interface 6.

Furthermore, before selecting the second template 5, the determination unit 44 may determine whether or not there are any unselected candidate templates in the logic pool area 41a during the time period in which the processing result continues to satisfy the detection condition. The candidate templates are the candidates for the template 5 that matches the read condition and represent one example of selectable templates 5 that have not been written to the circuit area 70 during the time period in which the processing result continues to satisfy the detection condition. Whether or not the candidate template has not yet been selected during the time period in which the processing result continues to satisfy the detection condition can be determined based on the “Timestamp” in the template management information 41c. This allows the determination unit 44 to avoid reading the template 5 that has been previously selected during the time period in which the detection condition is continued to be satisfied and that did not give an expected processing result, back into the FPGA 7. As a result, the processing result can be efficiently recovered.

For example, if the determination unit 44 determines that the processing result satisfies the detection condition, the determination unit 44 may refer to the template management information 41c and determine whether or not there is any candidate template for the second circuit logic that executes the second pre-process in the logic pool 40. If the determination unit 44 determines that there is an intended candidate template in the logic pool 40, the determination unit 44 may identify the candidate template from the template management information 41c using the above-described method and identify the FPGA 7 that matches the write condition from the template management information 41c.

Furthermore, the determination unit 44 may determine whether or not there is the intended candidate template in the shared pool storage 8 by referring to the template management information 82. This determination may be made, for example, when it is determined that there is no candidate template in the logic pool 40. If the determination unit 44 determines that there is the candidate template in the shared pool storage 8, the determination unit 44 may identify the candidate template to be moved to the logic pool 40, from the template management information 82 in the shared pool storage 8. The template management information 82 may include the items “Template No.”, “Logical Partition Size”, and “Processing Details”. The details of these items are similar to the template No., logical partition size, and processing details in the template management information 41c illustrated in FIG. 8.

Furthermore, the determination unit 44 may determine whether or not the candidate template can be generated by the generation unit 45, which will be described later. This determination may be made, for example, when it is determined that there is no candidate template in the shared pool storage 8. Conceivable situations where a candidate template cannot be generated include situations where the number of the templates 5 in the logic pool 40 is insufficient, or there is no template 5 that can be generated.

As a method for adding the template 5 to the logic pool 40, a method would be conceivable in which the template 5 is added through user's operations via the IF device 4e (see FIG. 4), but this method is not applicable for real-time or 5 near-real-time replacement of the template 5. On the contrary, according to the method according to one embodiment, the optimization apparatus 4 can set the second circuit logic that is implemented by the second template 5 and is not present in the logic pool 40, without requiring user's operations. Therefore, the templates 5 is rewritten in a shorter time compared to adding the template 5 through user's operations.

If there is no more candidate template during the time period in which the processing result continues to satisfy the detection condition, the determination unit 44 may select a fourth template 5 based on the information about the first process, from one or more second templates 5 set in the circuit area 70 during that time period. For example, if there is no more selectable candidate template, the determination unit 44 may select the best template 5 in the logic pool 40 based on the “Processing Results” in the template management information 41c. For example, the determination unit 44 may identify the template 5 that gives the best processing result during the time period in which the detection condition is satisfied, as the template 5 to be written to the FPGA 7. The template 5 that gives the best processing result represents one example of the fourth template. If the determination unit 44 determines that the candidate template is to be generated by the generation unit 45, the determination unit 44 may notify the generation unit 45 to generate the candidate template.

Furthermore, the determination unit 44 may determine to move the template 5 in the logic pool 40 to the shared pool storage 8, based on the memory usage of the memory unit 41. The template 5 moved to the shared pool storage 8 represents one example of a third template. For example, the determination unit 44 may refer to the timestamps in the template management information 41c and determine to move templates 5 with old timestamps to the shared pool storage 8 in ascending order of timestamp of the templates 5, starting from the oldest templates 5, until the memory usage of the logic pool 40 is reduced to a tolerable limit. Once the template 5 is moved to the shared pool storage 8, the determination unit 44 may add the entry for the template 5 to the template management information 82.

This prevents situations where a new template 5 cannot be added because of the shortage of the capacity in the optimization apparatus 4. Furthermore, the templates 5 for achieving the optimization of the system 1 may differ depending on the time or by region. For example, the template 5 that was considered the best for optimizing the processing result in a region may no longer be the best at a certain point in time, and may be unused for a prolonged time. However, this template 5 may be suitable for optimization of the processing result in other regions different from that region. Therefore, by moving the template 5 to the shared pool storage 8 and sharing it with the logic pools 40 of other regional systems 10, optimization of the processing result may be achieved in other regions.

Furthermore, the determination unit 44 may update the information 41b and 41c stored in the memory unit 41 after the write unit 47, which will be described later, writes the template 5 to the circuit area 70, and after the updating unit 48, which will be described later, updates a template 5 in the logic pool 40.

For example, when the template 5 generated by the generation unit 45, which will be described later, or the template 5 read from the shared pool storage 8 is added to the logic pool 40, the determination unit 44 may add the entry for the added template 5 to the template management information 41c. Furthermore, when the template 5 is changed in the logic pool 40 or deleted from the logic pool 40, the determination unit 44 may update or delete the corresponding entry in the template management information 41c.

Additionally, the determination unit 44 may update the template management information 41c based on the usage status of the template 5. As one example, the determination unit 44 may update the “FPGA No.”, “Timestamp”, and “Processing Results”. The “Processing Results” may include the recognition rate of the AI process using the result of the pre-process according to the template 5 and the operating rate of the FPGA 7 when the template 5 is used, and the determination unit 44 may, for example, update the “Processing Results” with the average of the recognition rates and the average of the operating rates over the given time period.

Furthermore, if the “Details” in the determination condition management information 41b is changed due to the addition, modification, or deletion of the template 5, for example, the determination unit 44 may update each entry in the determination condition management information 41b to reflect the change. The determination condition management information 41b may be updated, for example, in response to a determination condition update request, which will be described later.

The generation unit 45 generates the template 5 matching the read condition, based on the notification of the determination to generate the template 5 made by the determination unit 44. For example, the generation unit 45 may generate (compile) the template 5 matching the read condition based on one or more templates 5. For example, the generation unit 45 may generate the template 5 matching the read condition by combining a plurality of templates 5 contained in either or both the logic pool 40 and the shared pool storage 8. As an example, the generation unit 45 may generate the template 5 matching the read condition by combining a plurality of processing contents (processing elements) contained in each of the plurality of the templates 5 and performing recompiling. Alternatively, the generation unit 45 may generate the new template 5 by deleting at least one of the processing elements contained in a single template 5.

It should be noted that the generation unit 45 may generate the template 5 through input of a design (Process P1), design synthesis (Process P2), and implementation of the design (Process P4) as illustrated in FIG. 2 to generate the new template 5 by combining existing processing elements. The generation unit 45 may store the generated template 5 in the logic pool 40. In other words, the generation unit 45 may omit the execution of processes of the verification of the logic (Process P3), static timing analysis (Process P5), timing verification (Process P7), and actual machine verification (Process P9) illustrated in FIG. 2.

Furthermore, when the generation unit 45 uses the template 5 from the shared pool storage 8 for generating the new template, the generation unit 45 may refer to the template management information 82 to identify the template 5 and read it into the logic pool 40 or the memory 4c.

Compared to adding the new template 5 to the logic pool 40 through user's operations, the process of the generation unit 45 described above allows for the addition of the template 5 effective for optimization in a short time.

The generation unit 45 stores the generated template 5 in the logic pool 40 and notifies the determination unit 44 of the generation of the template 5. The determination unit 44 may register the information of the stored template 5 in the template management information 41c.

The read unit 46 reads the template 5 identified by the determination unit 44 or the generation unit 45 from the logic pool 40. For example, the read unit 46 reads the template 5 identified by the determination unit 44 from the logic pool 40, which is implemented by a part of the storage area in the memory unit 4d, and writes the template 5 to the memory 4c.

Alternatively, the read unit 46 may read the template 5 identified by the determination unit 44 from the shared pool storage 8. For example, the read unit 46 may read the template 5 identified by the determination unit 44 from the shared pool storage 8 and write the template 5 to the logic pool 40.

Furthermore, if the determination unit 44 determines to move the template 5 that has not been used for a long period to the shared pool storage 8, the read unit 46 may read the template 5 identified by the determination unit 44 from the logic pool 40 and write the template 5 to the shared pool storage 8.

The write unit 47 writes the template 5, which has been written to the memory 4c by the read unit 46, to the circuit area 70 in the FPGA 7 identified by the determination unit 44 via the communication path 1a. As a method of writing the template 5 to the circuit area 70 by the write unit 47, a method similar to the downloading of a bitstream to the circuit area 70 (Process P8 in FIG. 2) may be adopted. Once the writing of the template 5 is completed, the write unit 47 notifies the determination unit 44 of the completion.

The updating unit 48 updates the template 5 stored in the logic pool 40 based on a template update request from the user. The template update request represents one example of a registration request for the template 5, and may include a storing request to add the new template 5, a modification request to change the existing template 5, a deletion request to delete the existing template 5, and the like.

For example, when the updating unit 48 receives the storing request containing the information of the new template 5, the updating unit 48 may store the template 5 in the logic pool 40. Alternatively, for example, when the updating unit 48 receives the modification request containing the information of a destination template 5 and the information identifying a source template 5, the updating unit 48 may replace the source template 5 in the logic pool 40 with the destination template 5. Alternatively, for example, when the updating unit 48 receives the deletion request including the information identifying the template 5 stored in the logic pool 40, the updating unit 48 may delete the template 5 from the logic pool 40. Once the process in response to the template update request is completed, the updating unit 48 notifies the determination unit 44 of the completion.

For example, the updating unit 48 may receive the template update request from the host PC 3 or a computer not illustrated in the drawings via a network such as a LAN. Alternatively, the updating unit 48 may obtain the template update request input through the IO device 4f or the read unit 4g by the administrator or user of the system 1.

The template update request may also include the determination condition update request for updating the determination condition that changes with the update of the template 5. The determination condition update request represents one example of a registration request for a condition. The determination condition update request may contain information about a modification or deletion of an existing condition in the determination condition management information 41b or information about a new condition to be added to the determination condition management information 41b. The determination condition update request may be sent independently from the template update request from the host PC 3 or a computer not illustrated in the drawings, or may be inputted via the IO device 4f or the read unit 4g.

### (E) Example of Operation

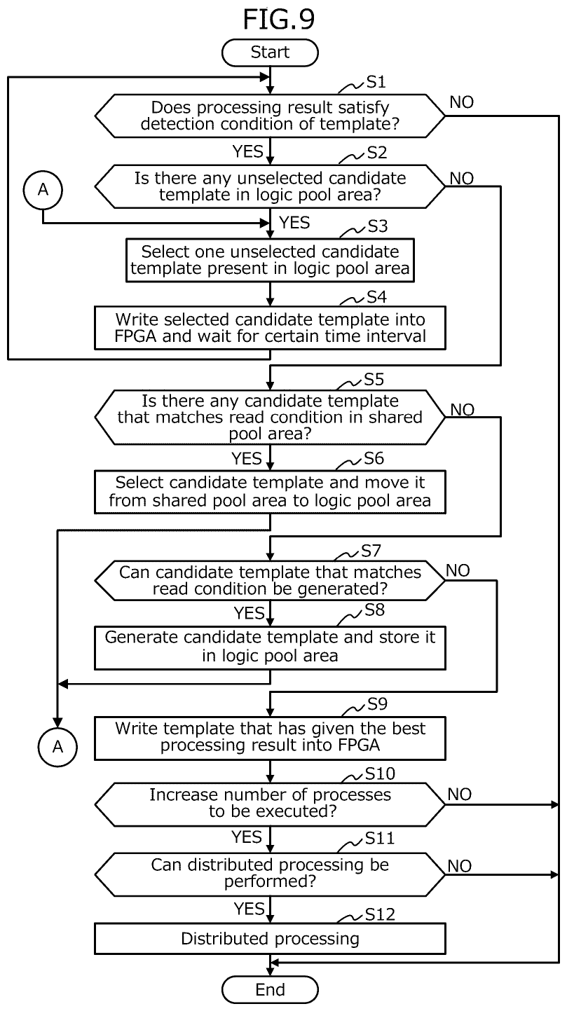

Next, an example of the operation of the system 1 according to one embodiment will be described. FIG. 9 is a flowchart illustrating an example of an operation of the system 1 according to one embodiment. Hereinafter, an example of the above-described process by the system 1 (e.g., the optimization apparatus 4) will be described with reference to the flowchart.

As illustrated in FIG. 9, the determination unit 44 in the optimization apparatus 4 determines whether or not a processing result obtained by the information collection unit 43 satisfies the detection condition in the determination condition management information 41b (Step S1). In this case, satisfying the detection condition means that the processing result is not in the expected state, such as when the low recognition rate or the high operating rate is observed, for example.

If it is determined by the determination unit 44 that the detection condition is not satisfied (NO in Step S1), the process ends. If it is determined by the determination unit 44 that the detection condition is satisfied (YES in Step S1), the process proceeds to Step S2.

The determination unit 44 refers to the determination condition management information 41b and the template management information 41c and determines whether or not there is any candidate template that has not been unselected in the logic pool area 41a, from among the templates that match the read condition (Step S2). The unselected candidate template refers to the template 5 that has not been used during the time period in which the processing result continues to satisfy the detection condition in Step S1, and the determination unit 44 determines whether a certain template 5 has been selected or not based on the timestamp in the template management information 41c.

If it is determined by the determination unit 44 that there is the unselected candidate template in the logic pool area 41a (YES in Step S2), the process proceeds to Step S3. The determination unit 44 refers to the template management information 41c to select one unselected candidate template present in the logic pool area 41a (the logic pool 40) (Step S3) and notifies the read unit 46 of the selected candidate template, and the process proceeds to Step S4.

The read unit 46 reads the selected candidate template from the logic pool 40 into the memory 4c. The write unit 47 writes the candidate template stored in the memory 4c into the circuit area 70 in the FPGA 7. This causes the FPGA 7 to operate according to the circuit logic implemented by the written candidate template. The optimization apparatus 4 then waits for a certain (given) time interval (Step S4), and the process proceeds to Step S1.

If it is determined by the determination unit 44 that there is no unselected candidate template in the logic pool area 41a (NO in Step S2), the process proceeds to Step S5. The determination unit 44 refers to the template management information 82 in the shared pool storage 8 and determines whether or not there is any candidate template that matches the read condition in the shared logic pool area 81 (Step S5).

If it is determined by the determination unit 44 that there is the candidate template that matches the read condition in the shared logic pool area 81 (YES in Step S5), the process proceeds to Step S6. In Step S6, the determination unit 44 selects the candidate template that matches the read condition from the shared logic pool area 81. The read unit 46 moves the selected candidate template to the logic pool area 41a. As a result, the candidate template that has not been selected yet is added to the logic pool area 41a. The process then proceeds to Step S3.

If it is determined by the determination unit 44 that there is no candidate template that matches the read condition in the shared logic pool area 81 (NO in Step S5), the process proceeds to Step S7. The determination unit 44 refers to the template management information 41c and 82 and determines whether or not the candidate template that matches the read condition can be generated (Step S7).

If it is determined by the determination unit 44 that the candidate template that matches the read condition can be generated (YES in Step S7), the generation unit 45 generates the candidate template that matches the read condition and stores the generated candidate template in the logic pool area 41a (Step S8). As a result, the candidate template that has not been selected yet is added to the logic pool area 41a. The process then proceeds to Step S3.

If it is determined by the determination unit 44 that the candidate template that matches the read condition cannot be generated (NO in Step S7), the process proceeds to Step S9. In Step S9, the determination unit 44 selects the template 5 that is confirmed to give the best processing result from among templates set in the circuit areas 70 during the time period in which the detection condition continues to be satisfied. For example, the determination unit 44 refers to the timestamp and the processing result in the template management information 41c and selects the template 5 that gives the best processing result during the time period in which the detection condition continues to be satisfied. The read unit 46 stores the selected template 5 in the memory 4c. The write unit 47 sets the stored template 5 in the circuit area 70, and the process proceeds to Step S10.

After the processing in Step S9, regardless of whether or not the distributed processing in Step S12, which will be described later, is executed, the determination unit 44 may consider that the detection condition that continued to be satisfied is no longer satisfied. This causes the time period in which the detection condition continued to be satisfied to be terminated.

In Step S10, the determination unit 44 determines whether or not to increase the number of processes to be executed. The number of processes is increased, for example, when the logical partition size of the template 5 written in

Step S9 is larger than the size of the circuit logic that has been set before the writing. If it is determined by the determination unit 44 not to increase the number of processes (NO in Step S10), the process ends.

If it is determined by the determination unit 44 to increase the number of processes (YES in Step S10), the determination unit 44 determines whether or not distributed processing can be performed (Step S11). For example, the determination unit 44 may determine whether or not distributed processing can be performed based on the imbalance among the processing loads (operating rates) on multiple FPGAs 7. For example, a case is assumed where the template 5 with a large size is written to the FPGA #0 from among the FPGA #0 to #2. In this case, if the operating rates of the FPGA #1 and #2 are on a decreasing trend, the determination unit 44 may determine that the process in the FPGA #0 is to be written to the circuit area 70 in the FPGA #1 or the FPGA #2. The above-described determination may be made based on the determination condition related to distributed processing included in the determination condition management information 41b (see the condition name R3 in FIG. 7, for example).

If it is determined by the determination unit 44 that distributed processing cannot be performed (NO in Step S11), the process ends. For example, distributed processing cannot be performed in the case where the processing loads on all FPGAs #7 are increasing or are constant.

If it is determined by the determination unit 44 that distributed processing can be performed (YES in Step S11), the determination unit 44 performs the distributed processing to distribute the process performed by the template 5 (Step S12), and the process ends. The distributed processing is performed by setting the template 5 set in the FPGA #7 with a high load, to the FPGA #7 with a low load.

In this manner, in Steps S1 to S8, the optimization apparatus 4 repeats the process of selecting candidate templates and writes them to the circuit area 70 until there is no more candidate template while the process result satisfies the detection condition.

It should be noted that the execution order of the processes in Steps S5 and S6, and the processes in Steps S7 Furthermore, either or both the and S8, may be swapped. processes in Steps S5 and S6, and the processes in Steps S7 and S8 may be omitted.

### (E-1) First Operation Example

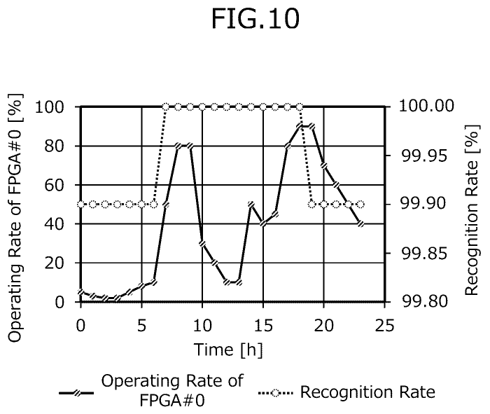

Next, a first operation example of the system 1 according to one embodiment will be described using FIG. 10 to FIG. 15.

FIG. 10 is a diagram illustrating a change in the processing results according to the first operation example. A horizontal axis of the graph in FIG. 10 represents time, and as an example, it represents the processing results from 00:00 to 24:00 on a certain day. A left vertical axis represents the operating rate of the FPGA #0, and a right vertical axis represents the AI recognition rate by the host PC 3. The graph in a solid line connects the operating rates of the FPGA #0 (diagonal hatched circles) obtained at the given time intervals, and the graph in the dashed line connects the AI recognition rates by the host PC 3 (hollow circles) obtained at the given time intervals.

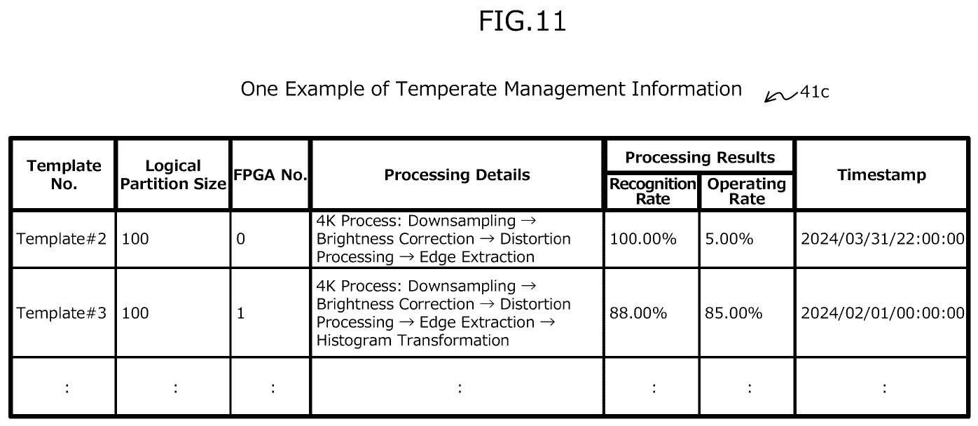

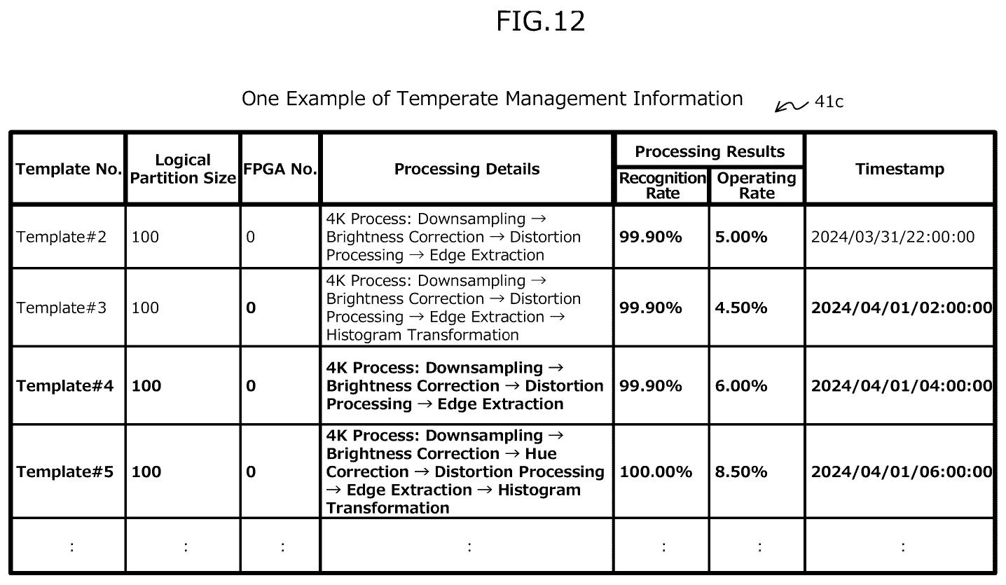

FIG. 11 is a diagram illustrating the template management information 41c according to the first operation example, and FIG. 12 is a diagram illustrating updates to the template management information 41c in the first operation example. In FIG. 11 and FIG. 12, one example of the template management information 41c focusing on the 4K processing, which is the process for the same resolution as the resolution of Process A executed by the FPGA #0, is illustrated. As one example, the determination unit 44 may filter (narrow down) the “Processing Details” in the template management information 41c by the 4K processing to obtain the template management information 41c illustrated in FIG. 11 and FIG. 12. It is assumed that the template #0 is operating in the circuit area 70 in the FPGA #2, at the starting point of the graph illustrated in FIG. 10.

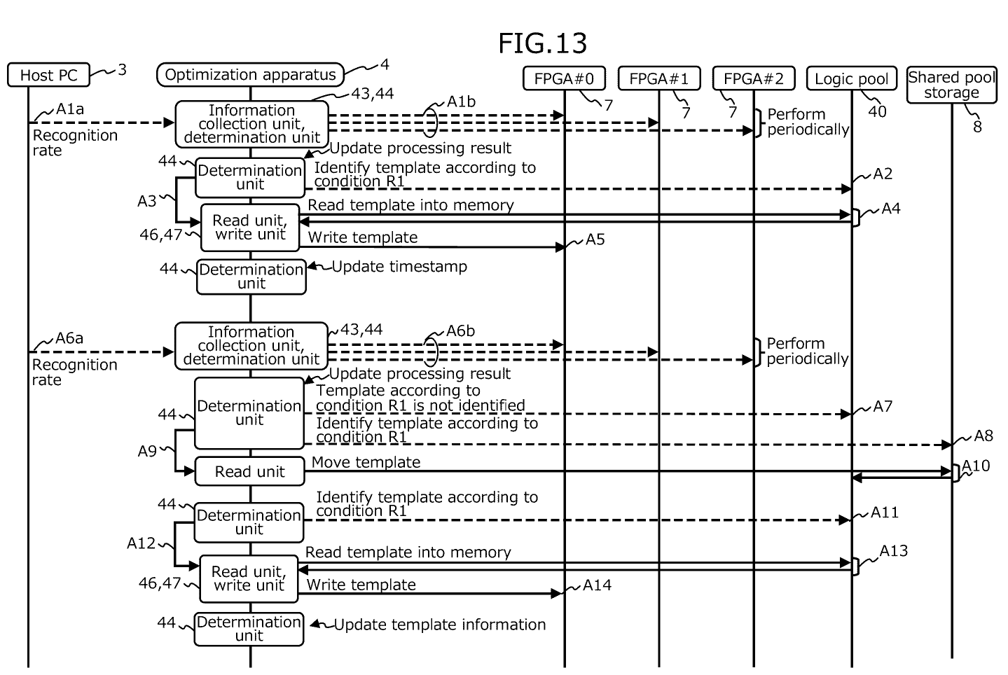

FIG. 13 to FIG. 15 are sequence diagrams illustrating the first operation example of the system 1 according to one embodiment.

As exemplified in FIG. 13, the information collection unit 43 in the optimization apparatus 4 collects the operating rates of the FPGAs 7 based on the recognition rate by the host PC 3 and the network transfer volume of each FPGA 7 periodically. The determination unit 44 determines whether or not the detection condition in the determination condition management information 41b is matched based on the collected information (Processes A1a and A1b).

In the example in FIG. 10, the information collection unit 43 collects the processing result with the recognition rate of 99.90% for the given time intervals starting from 0:00. The determination unit 44 determines that the detection condition of the determination condition R1 in the determination condition management information 41b illustrated in FIG. 7 is matched. The determination unit 44 sets the processing results of the template #2 for the given time in the past in the template management information 41c, as indicated in bold in FIG. 12.

Furthermore, the determination unit 44 refers to the template management information 41c and identifies the template #3 as the candidate template that matches the read condition of the condition R1 present in the logic pool 40 (Process A2), then notifies the read unit 46 and the write unit 47 of it (Process A3). The determination unit 44, using the template management information 41c illustrated in FIG. 11, may identify the template #3, which is of the same resolution as the template #2 and includes the processing element “Histogram Transformation” in addition to the processing elements in the template #2, as the candidate template that matches the read condition. The notification may include the template #3 identified by the determination unit 44 and determination condition R1.

After the notification from the determination unit 44, the read unit 46 reads the template #3 from the logic pool 40 (e.g., the memory unit 4d) (Process A4), and stores the read template #3 in the memory 4c.

The write unit 47 writes the template #3 stored in the memory 4c to the logical partition in the circuit area 70 in the FPGA #0, according to the write condition of the condition R1, via the communication path 1a (Process A5), then notifies the determination unit 44 of the completion of the write operation. Subsequently, in response to the execution request from the host PC, the FPGA #0 performs the pre-process by the circuit logic of the template #3 that has been written. Based on the writing result to the template #3, the determination unit 44 updates the “Timestamp” for the template #3 to the date and time when the template #3 was written, and updates the “FPGA No.” to “0”, in the template management information 41c, as indicated in bold in FIG. 12.

As exemplified in FIG. 13, the information collection unit 43 continues to collect the processing results from the FPGA #0 to which the template #3 has been set, and the determination unit 44 determines whether or not the detection condition in the determination condition management information 41b is matched based on the collected information (Processes A6a and A6b).

If the recognition rate is still not recovered even after a given time after the template #3 is rewritten to the circuit area 70 in the FPGA #0, the determination unit 44 determines that the detection condition of the condition R1 is matched. The determination unit 44 updates the “Processing Results” for the template #3 in the template management information 41c, as exemplified in bold in FIG. 12.

Furthermore, the determination unit 44 refers to the template management information 41c and determines that the candidate template that matches the read condition of the condition R1 is not identified in the logic pool 40 (Process A7). This is because, as exemplified in FIG. 11, the only candidate template that has the same resolution as the resolution of the template #3 set in the FPGA #0 is the template #2, and it is determined that the template #2 has already been used based on the timestamp once the determination condition of the condition R1 is matched.

In this case, the determination unit 44 refers to the template management information 82 in the shared pool storage 8 via the network, and identifies the template #4 as the candidate template that matches the read condition of the condition R1 (Process A8), then notifies the read unit 46 of it (Process A9).

After the notification from the determination unit 44, the read unit 46 reads the template #4 from the shared logic pool area 81 in the shared pool storage 8 (Process A10), then stores the read template #4 in the memory 4c.

The determination unit 44 refers to the template management information 41c, identifies the template #4, which has been newly added to the logic pool 40 in Process A10, as the candidate template that matches the read condition of the condition R1 (Process A11), and notifies the read unit 46 and the write unit 47 of it (Process A12).

After the notification from the determination unit 44, the read unit 46 reads the template #4 from the logic pool 40 (Process A13), and stores the read template #4 in the memory 4c.

The write unit 47 writes the template #4 stored in the memory 4c to the logical partition in the circuit area 70 in the FPGA #0 according to the write condition of the condition R1, via the communication path 1a (Process A14), and notifies the determination unit 44 of the completion of the write operation. Subsequently, in response to the execution request from the host PC, the FPGA #0 performs the pre-process by the circuit logic according to the template #4 that has been written. The determination unit 44 adds the information of the template #4 read from the shared pool storage 8 to the template management information 41c, as indicated in bold in FIG. 12. Furthermore, based on the writing result of the template #4, the determination unit 44 updates the “Timestamp” to the date and time when the template #4 was written, and updates the “FPGA No.” to “0”.

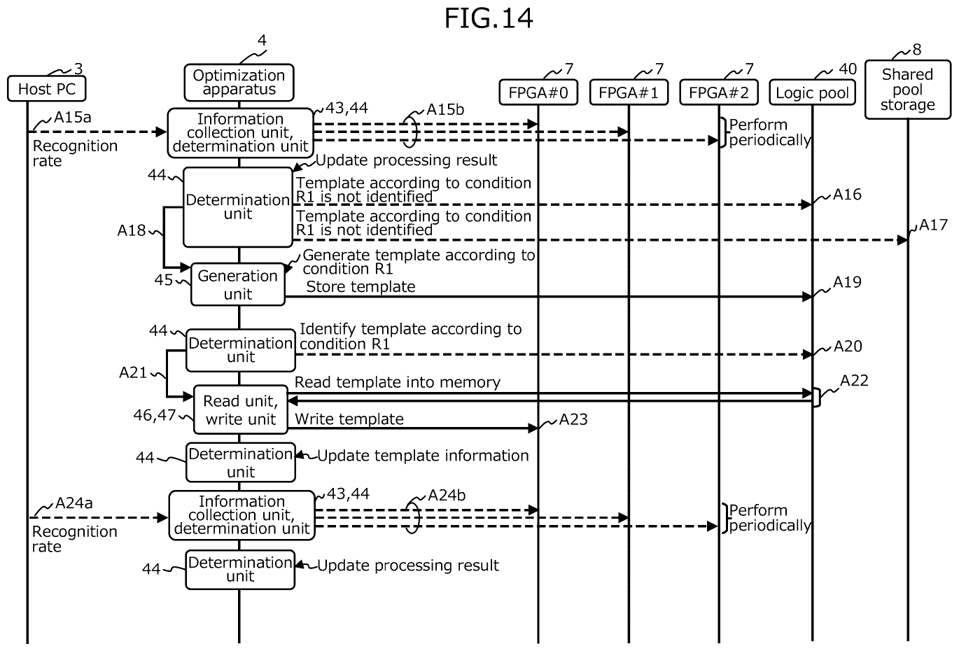

Subsequently, as exemplified in FIG. 14, the information collection unit 43 continues to collect the processing results from the FPGA #0 to which the template #4 has been set, and the determination unit 44 determines whether or not the detection condition is matched based on the collected information (Processes A15a and A15b). If the recognition rate is still not recovered even after a given time after the template #4 is rewritten, the determination unit 44 determines that the detection condition of the condition R1 is matched, and updates the “Processing Results” for the template #4 in the template management information 41c, as exemplified in bold in FIG. 12.

Furthermore, the determination unit 44 refers to the template management information 41c and determines that the candidate template that matches the read condition of the condition R1 is not identified in the logic pool 40 (Process A16). This is because it is determined that the candidate templates having the same resolution as the resolution of the template #4, namely, the templates #2 and #3, have already been used based on the timestamp once the determination condition of the condition R1 is matched.

Additionally, the determination unit 44 refers to the template management information 82 and determines that the candidate template that matches the read condition of the condition R1 is not identified in the shared pool storage 8 (Process A17), and notifies the generation unit 45 of it (Process A18). For example, if there is no candidate template with the resolution of “4K processing” in the shared pool storage 8, no candidate template in the shared pool storage 8 is identifiable.

Subsequently, if it is determined by the determination unit 44 that the new candidate template that matches the read condition of the condition R1 can be generated, the generation unit 45 generates a template #5 that matches the read condition of the condition R1 and stores it in the logic pool 40 (Process A19). The generation unit 45 notifies the determination unit 44 that the template #5 has been generated.

The determination unit 44 refers to the template management information 41c, identifies the newly added template #5 in the logic pool 40 as the candidate template that matches the read condition of the condition R1 (Process A20), and notifies the read unit 46 and the write unit 47 of it (Process A21).

After the notification from the determination unit 44, the read unit 46 reads the template #5 from the logic pool 40 (Process A22) and stores the read template #5 in the memory 4c.

The write unit 47 writes the template #5 stored in the memory 4c to the logical partition in the circuit area 70 in the FPGA #0, according to the write condition of the condition R1, via the communication path 1a (Process A23), and notifies the determination unit 44 of the completion of the writing. Thereafter, in response to the execution request from the host PC 3, the FPGA #0 executes the pre-process by the circuit logic implemented by the written template #5.

As exemplified in FIG. 12, the determination unit 44 adds the information of the template #5 to the template management information 41c. Based on the writing result of the template #5 by the write unit 47 to the FPGA #0, the determination unit 44 updates the “Timestamp” for the template #5 of the template management information 41c to the date and time when the template #5 was written and updates the “FPGA No.” to “0” in the template management information.

Subsequently, as exemplified in FIG. 14, the information collection unit 43 continues to collect the processing results from the FPGA #0 to which the template #5 has been set, and the determination unit 44 determines whether or not the detection condition is matched based on the collected information (Processes A24a and A24b).

For example, in the graph of the change in the processing results exemplified in FIG. 10, the recognition rate is recovered to 100% at 7:00. In this case, the determination unit 44 determines that the detection condition is not matched based on the determination condition management information 41b. Furthermore, the determination unit 44 updates the “Processing Results” for the template #5 in the template management information 41c, as exemplified in FIG. 12, and the processing ends.

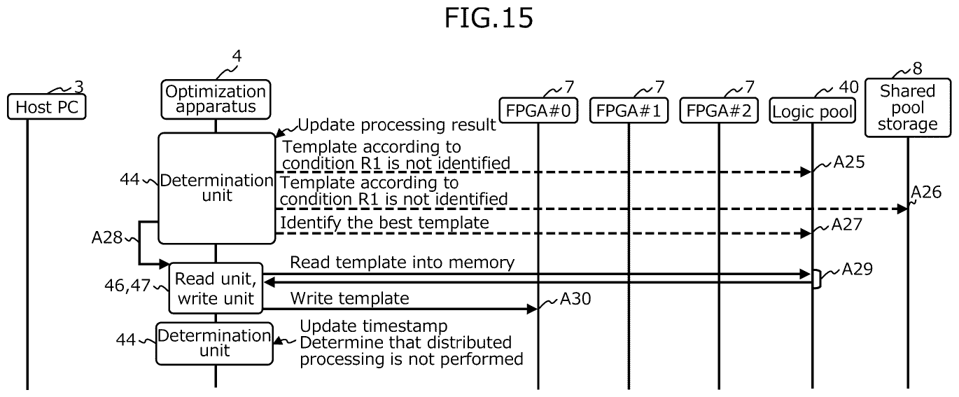

On the other hand, if the recognition rate is still not recovered even when the pre-process is executed by the FPGA #0 to which the template #5 has been set, the process illustrated in FIG. 15 is executed. FIG. 15 illustrates the continuation of the process when the determination unit 44 determines that the detection condition of the condition R1 continues to be matched even after the template #5 has been set in the FPGA #0 and the processing results are collected and determined (Processes A24a and A24b).

The determination unit 44 updates the “Processing Results” for the template #5 in the template management information 41c to 99.92%, for example. The determination unit 44 refers to the template management information 41c and determines that the candidate template that matches the read condition of the condition R1 is not identified in the logic pool 40 (Process A25).

Subsequently, the determination unit 44 refers to the template management information 82 and determines that the candidate template that matches the condition R1 is not identified in the shared pool storage 8 (Process A26). Furthermore, if it is determined by the determination unit 44 that the new candidate template cannot be generated by the generation unit 45, the determination unit 44 refers to the template management information 41c. The determination unit 44 identifies the candidate template that gives the best recognition rate during the time period in which the processing result continues to satisfy the detection condition of the condition R1, based on the “Processing Results” and the “Timestamp” (Process A27), and notifies the read unit 46 and the write unit 47 of it (Process A28).

The read unit 46 reads the template #5 identified by the determination unit 44 (Process A29) and stores the read template #5 in the memory 4c.

The write unit 47 writes the template #5 stored in the memory 4c to the logical partition in the circuit area 70 in the FPGA #0, via the communication path 1a (Process A30), and notifies the determination unit 44 of the completion of the writing.

Based on the writing result of the template #5 to the FPGA #0 by the write unit 47, the determination unit 44 updates the “Timestamp” for the template #5 in the template management information 41c to the date and time when the template #5 was written, and the processing ends.

### (E-2) Second Operation Example

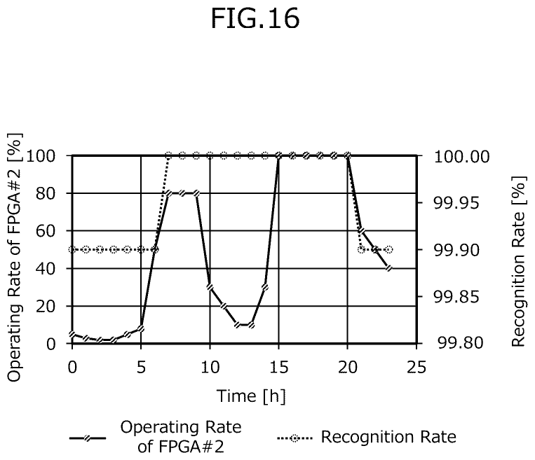

Subsequently, a second operation example of the system 1 according to one embodiment will be described using FIG. 16 to FIG. 20.

FIG. 16 is a diagram illustrating a change of the processing results according to the second operation example. A horizontal axis of the graph in FIG. 16 represents time, and as an example, it represents the processing results from 00:00 to 24:00 on a certain day. A left vertical axis represents the operating rate of the FPGA #2, and a right vertical axis represents the AI recognition rate by the host PC 3. The solid line in the graph connects the operating rates of the FPGA #2 (diagonal hatched circles) obtained at given time intervals, and the graph in the dotted line connects the AI recognition rates by the host PC 3 obtained at the given time intervals.

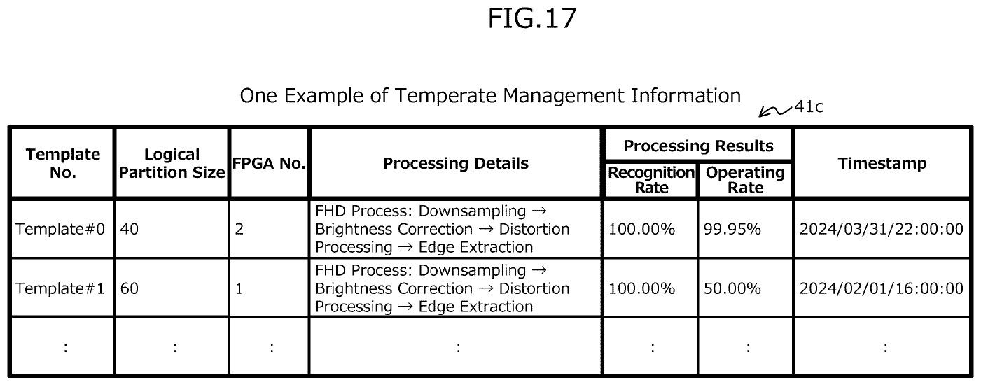

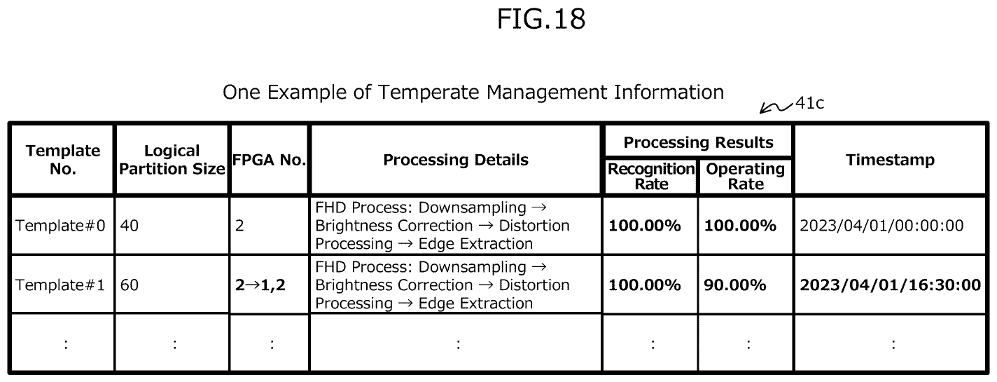

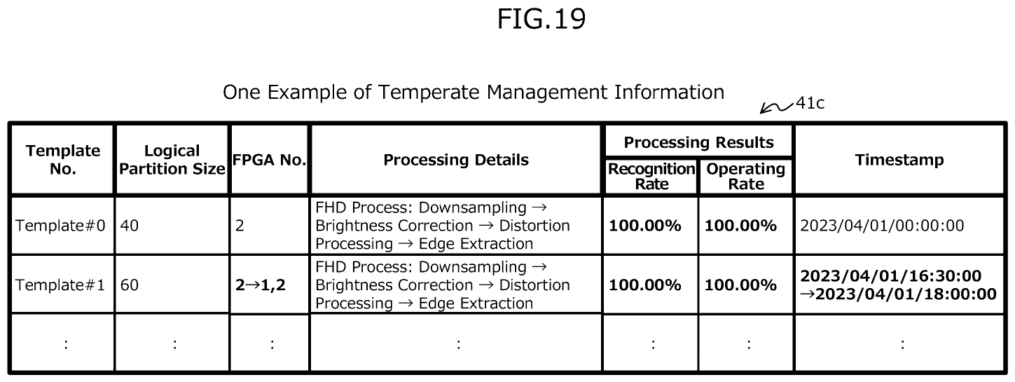

FIG. 17 is a diagram illustrating the template management information 41c according to the second operation example, and FIG. 18 and FIG. 19 are diagrams illustrating updates to the template management information 41c according to the second operation example. In FIG. 17 to FIG. 19, one example of the template management information 41c, focusing on the template #5 with the same processing contents as Process C executed by the FPGA #2, is illustrated. As one example, the determination unit 44 may obtain the template management information 41c illustrated in FIG. 17 to FIG. 19 by filtering the template management information 41c by the same “Processing Details”. It is assumed that the template #0 is operating in the circuit area 70 in the FPGA #2 at the starting point of the graph illustrated in FIG. 16.

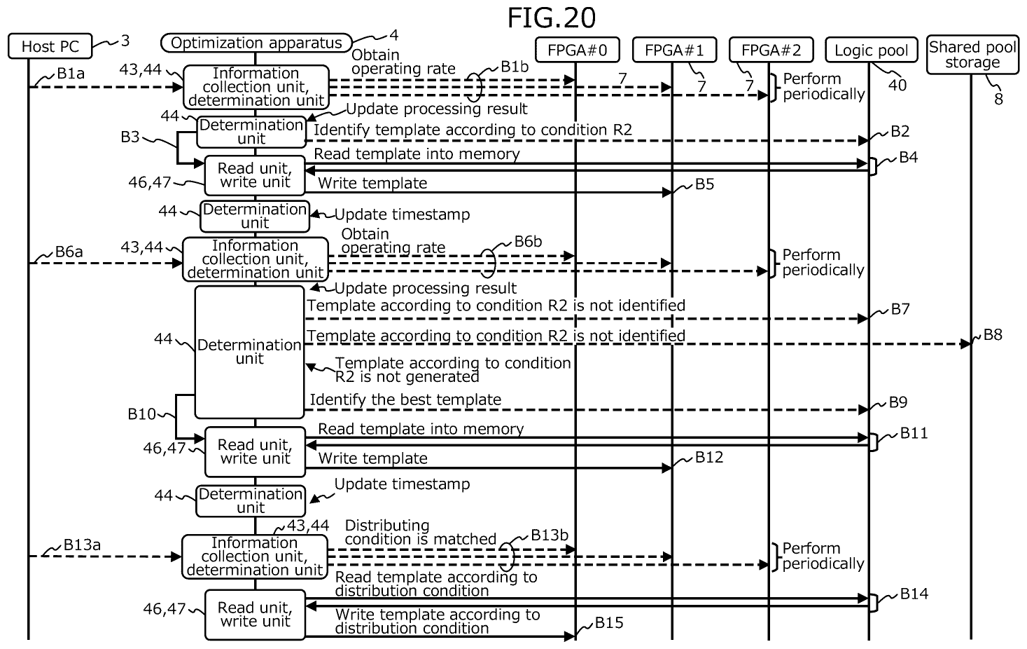

FIG. 20 is a sequence diagram illustrating the second operation example of the system 1 according to one embodiment.

As exemplified in FIG. 20, the information collection unit 43 in the optimization apparatus 4 collects the operating rates of the FPGAs 7 based on the recognition rate by the host PC 3 and the network transfer volume of each FPGA 7 periodically. The determination unit 44 determines whether or not the detection condition in the determination condition management information 41b is matched based on the collected information (Processes B1a and B1b).

In the example in FIG. 16, the operating rate is 100.00% from around 15:00. In the determination condition illustrated in FIG. 7, if the recognition rate is 100.00%, the determination unit 44 determines that the detection condition is matched because the determination condition R2 is satisfied. Furthermore, the determination unit 44 updates the “Processing Results” for the template #0 in the template management information 41c, as exemplified in bold in FIG. 18.

The determination unit 44 identifies the template #1 as the candidate template in the logic pool 40 that matches the read condition of the condition R2 from the template management information 41c (Process B2), and notifies the read unit 46 and the write unit 47 of it (Process B3). The determination unit 44 identifies the template #1, which has the same processing contents as the template #0, and has the circuit logic with a logical partition size larger than that of the template #0 and a size smaller than or equal to the circuit scale 71 of the FPGA #2. The notification may include the template #1 identified by the determination unit 44 and the condition R2.

After the notification by the determination unit 44, the read unit 46 reads the template #1 from the logic pool 40 (e.g., the memory unit 4d) (Process B4), and stores the read template #1 in the memory 4c.

The write unit 47 writes the template #1 stored in the memory 4c to the logical partition in the circuit area 70 in the FPGA #2, according to the write conditions for the condition R2, via the communication path 1a (Process B5), and notifies the determination unit 44 of the completion of the writing.

Based on the writing result of the template #1 to the FPGA #2 by the write unit 47, the determination unit 44 updates the “Timestamp” for the template #1 in the template management information 41c to the date and time when the template #1 was written, as illustrated in FIG. 18. Furthermore, based on the writing result of the template #1 to the FPGA #2, the determination unit 44 updates the “FPGA No.” of the template #1 in the template management information 41c to “2”, as illustrated in FIG. 18.

As exemplified in FIG. 20, the information collection unit 43 continues to collect the recognition rate and the operating rate of the FPGA #2 to which the template #1 has been set, and the determination unit 44 determines whether or not the detection condition in the determination condition management information 41b is matched based on the collected information (Processes B6a and B6b).

If the operating rate falls below 100.00% (e.g., 99.00%) after a given time period has elapsed after the template #1 is rewritten, the determination unit 44 determines that the detection condition of the condition R2 is no more matched. It should be noted that the determination unit 44 updates the “Processing Results” for the template #1 in the template management information 41c, as exemplified in bold in FIG. 18.

On the other hand, if the operating rate does not fall below 100.00% even after the given time period has elapsed after the template #1 is rewritten, the determination unit 44 determines that the detection condition of the condition R2 is matched. One example of the template management information 41c updated in this case is illustrated in FIG. 19. The determination unit 44 updates the “Processing Results” for the template #1 in the template management information 41c, as exemplified in bold in FIG. 19.

Subsequently, the determination unit 44 refers to the template management information 41c and determines that the candidate template that matches the read condition of the condition R2 is not identified in the logic pool 40 (Process Furthermore, the determination unit 44 refers to the B7). template management information 82 and determines that the candidate template is not also identified in the shared pool storage 8 if there is no candidate template that matches the read condition of the condition R2 (Process B8).

Furthermore, the determination unit 44 determines whether or not the candidate template according to the read conditions of the condition R2 can be generated by the generation unit 45. If the determination unit 44 determines that the new candidate template cannot be generated, the determination unit 44 refers to the template management information 41c, identifies the template #5 that gives the best processing result (Process B9), and notifies the read unit 46 and the write unit 47 of it (Process B10). In this case, there is no difference in operating rate between the template #0 and the template #1, but the template #1 may be considered the best due to its larger logical partition size.

The read unit 46 reads the template #1 identified by the determination unit 44 (Process B11), and stores the read template #1 in the memory 4c.

The write unit 47 writes the template #4 stored in the memory 4c to a logical partition in the circuit area 70 in the FPGA #2 via the communication path 1a (Process B12), and notifies the determination unit 44 of the completion of the writing.

Based on the writing result of the template #1 to the FPGA #2 by the write unit 47, the determination unit 44 updates the “Timestamp” for the template #1 in the template management information 41c to the date and time when the template #1 was rewritten, as illustrated in FIG. 19.

Subsequently, as illustrated in Processes B13a and B13b, a case is assumed where the operating rate of the FPGA 7 matches the distribution condition (the condition R3) in the determination condition management information 41b, in the determinations by the information collection unit 43 and the determination unit 44. In this case, the determination unit 44 notifies the read unit 46 and the write unit 47 of the distribution condition R3.

The read unit 46 reads the template #1 from the logic pool 40 (e.g., the storing device 4d) according to the read condition of the condition R3 (Process B14), and stores the read template #1 in the memory 4c.

The write unit 47 writes the template #1 stored in the memory 4c to the logical partition in the circuit area 70 in the FPGA #0, in which another template 5 has not been set, according to the write condition of the condition R3, via the communication path 1a (Process B15). Furthermore, the write unit 47 notifies the determination unit 44 of the completion of the writing. It should be noted that the logical partitions in the circuit area 70 in the FPGA #0, in which other templates 5 are set, continue to operate normally without being affected by the writing of the template #1.

Through the above-described operations, the writing process of the template 5 to the FPGA 7 (the process when the detection condition is satisfied) is completed.

### (F) Miscellaneous

The technology according to the embodiment described above may be modified or changed as follows.

For example, the functional blocks 42 to 48 provided in the optimization apparatus 4 illustrated in FIG. 6 may be combined in any combination or may be each divided. The information 41b and 41c stored in the memory unit 41 illustrated in FIG. 5 may be combined in any combination or may be each divided.

In addition, although the host PC 3 and the optimization apparatus 4 have been described as separate computers in one embodiment, this is not limiting. For example, the host PC 3 and the optimization apparatus 4 may be a single computer, or the host PC 3 may be provided with at least some of the functions or information provided in the optimization apparatus 4.

Furthermore, the logic pool 40 has been described as being provided in the optimization apparatus 4, but this is not limiting. The logic pool 40 may be provided in a computer or storage device different from the optimization apparatus 4. In this case, the read unit 46 may read a template 5 from the logic pool 40 via the IF device 4e, and the updating unit 48 may update the template 5 in the logic pool 40 via the IF device 4e.

Moreover, in one embodiment, the FPGAs 7 have been described as examples of the programmable logic circuit, but this is not limiting and the approach according to one embodiment can also be applied to cases where a Complex PLD (CPLD) is used. It should be noted that templates 5 for the CPLD may be bitstream data in which placement and routing of the circuit logics (also referred to as “fit”) has been completed, similar to the templates 5 in the FPGAs 7.

Furthermore, in one embodiment, processing in each of the situation where the recognition rate is low or the situation where the operating rate is high (see FIG. 10 to FIG. 12) has been described as an example, but this is not limiting. For example, a determination condition for determining a low recognition rate and high operating rate may be provided in the determination condition management information 41b. If this condition is met, the determination unit 44 may identify the template 5 for recovering the recognition rate and lowering the operating rate, either from the logic pool 40 or the shared pool storage 8, or may cause the generation unit 45 to generate the template 5, as a candidate template that matches the condition.

This allows for recovery of the recognition rate or reduction of the operating rate in situations where the recognition rate is low and the operating rate is high, such as when the AI process is performed on many objects in a dark environment or when a large-scale disaster occurs at night.

Additionally, the timing to update the information in the template management information 41c by the determination unit 44 is not limited to the timing described in the above embodiment. For example, the “Timestamp” and “FPGA No.” may be updated simultaneously with the update of the “Processing Results”.

Furthermore, one embodiment has been described that the process of identifying the candidate template from the template management information 82 in the shared pool storage 8 is performed if there is no candidate template in the logic pool 40, but the number of candidate templates identified are not limited to one. For example, multiple candidate templates that match the read condition may be read from the shared pool storage 8 and are moved to the logic pool 40 at once.

In one aspect, the present disclosure can improve the processing efficiency of programmable logic circuits.

Throughout the descriptions, the indefinite article “a” or “an”, or adjective “one” does not exclude a plurality.

All examples and conditional language recited herein are intended for the pedagogical purposes of aiding the reader in understanding the invention and the concepts contributed by the inventor to further the art, and are not to be construed limitations to such specifically recited examples and conditions, nor does the organization of such examples in the specification relate to a showing of the superiority and inferiority of the invention. Although one or more embodiments of the present inventions have been described in detail, it should be understood that the various changes, substitutions, and alterations could be made hereto without departing from the spirit and scope of the invention.

What is claimed is:

1. A control apparatus comprising:
a memory; and
a processor coupled to the memory, the processor being configured to execute a process comprising:
reading, when information about a first process executed by a first circuit logic corresponding to a first template satisfies a given condition, a second template for a second circuit logic that executes a second process related to the first process from a storage area to obtain a read second template, the first circuit logic being set in a rewritable circuit area provided in a programmable logic circuit, the first circuit logic being implemented by writing the first template of which a circuit design synthesis has been completed and of which placement and routing have been already determined, into the circuit area; and
writing the read second template into the circuit area to set the second circuit logic that executes the second process in the circuit area.

2. The control apparatus according to claim 1, wherein
the information about the first process includes an indicator indicating desirability of a result obtained by inputting a result of the first process into a machine learning model, and
the reading includes reading, when a first condition among a plurality of the given conditions that the indicator is less than a first given value is satisfied, the second template for the second circuit logic that executes the second process, from the storage area, the second process including a plurality of processing elements to which at least one of deletion of one or more processing elements, replacement of one or more processing elements, and addition of one or more processing elements, from among a plurality of processing elements included in the first process, has been applied.

3. The control apparatus according to claim 1, wherein
the information about the first process includes information about a load on the first circuit logic that executes the first process, and
the reading includes reading, when a second condition among a plurality of the given conditions that the information about the load is equal to or greater than a second given value is satisfied, the second template for the second circuit logic with a size larger than a size of the first circuit logic, from the storage area.

4. The control apparatus according to claim 1, wherein
the processor stores, into the storage area, a selectable template that has not been written into the circuit area during a time period in which the given condition continues to be satisfied, from a shared storage area shared among a plurality of the control apparatuses.

5. The control apparatus according to claim 4, wherein
the processor moves a third template that is selected based on an unused time period from among the plurality of templates stored in the storage area, to the shared storage area, according to a usage of the storage area.

6. The control apparatus according to claim 1, wherein
the processor generates a selectable template that has not been written into the circuit area during a time period in which the given condition continues to be satisfied, based on one or more templates stored in the storage area.

7. The control apparatus according to claim 1, wherein
the processor
writes, when there is no more selectable template that has not been written into the circuit area during a time period in which the given condition continues to be satisfied, a fourth template selected based on the information about the first process from one or more of the second templates set in the circuit area during the time period, into the circuit area; and
terminates the time period.

8. A computer-implemented control method executed by a computer, the control method comprising:
reading, when information about a first process executed by a first circuit logic corresponding to a first template satisfies a given condition, a second template for a second circuit logic that executes a second process related to the first process from a storage area to obtain a read second template, the first circuit logic being set in a rewritable circuit area provided in a programmable logic circuit, the first circuit logic being implemented by writing the first template of which a circuit design synthesis has been completed and of which placement and routing have been already determined, into the circuit area; and
writing the read second template into the circuit area to set the second circuit logic that executes the second process in the circuit area.

9. The computer-implemented control method according to claim 8, wherein
the information about the first process includes an indicator indicating desirability of a result obtained by inputting a result of the first process into a machine learning model, and
the reading includes reading, when a first condition among a plurality of the given conditions that the indicator is less than a first given value is satisfied, the second template for the second circuit logic that executes the second process, from the storage area, the second process including a plurality of processing elements to which at least one of deletion of one or more processing elements, replacement of one or more processing elements, and addition of one or more processing elements, from among a plurality of processing elements included in the first process, has been applied.

10. The computer-implemented control method according to claim 8, wherein
the information about the first process includes information about a load on the first circuit logic that executes the first process, and
the reading includes reading, when a second condition among a plurality of the given conditions that the information about the load is equal to or greater than a second given value is satisfied, the second template for the second circuit logic with a size larger than a size of the first circuit logic, from the storage area.

11. The computer-implemented control method according to claim 8, wherein the control method further comprises
storing, into the storage area, a selectable template that has not been written into the circuit area during a time period in which the given condition continues to be satisfied, from a shared storage area shared among a plurality of the control apparatuses.

12. The computer-implemented control method according to claim 11, wherein the control method further comprises
moving a third template that is selected based on an unused time period from among the plurality of templates stored in the storage area, to the shared storage area, according to a usage of the storage area.

13. The computer-implemented control method according to claim 8, wherein the control method further comprises
generating selectable template that has not been written into the circuit area during a time period in which the given condition continues to be satisfied, based on one or more templates stored in the storage area.

14. The computer-implemented control method according to claim 8, wherein the control method further comprises:
writing, when there is no more selectable template that has not been written into the circuit area during a time period in which the given condition continues to be satisfied, a fourth template selected based on the information about the first process from one or more of the second templates set in the circuit area during the time period, into the circuit area; and
terminating the time period.

15. A distributed processing system comprising:
a programmable logic circuit; and
a control apparatus,
the control apparatus comprising:
a memory; and
a processor coupled to the memory, the processor being configured to execute a process comprising:
reading, when information about a first process executed by a first circuit logic corresponding to a first template satisfies a given condition, a second template for a second circuit logic that executes a second process related to the first process from a storage area to obtain a read second template, the first circuit logic being set in a rewritable circuit area provided in the programmable logic circuit, the first circuit logic being implemented by writing the first template of which a circuit design synthesis has been completed and of which placement and routing have been already determined, into the circuit area; and
writing the read second template into the circuit area to set the second circuit logic that executes the second process in the circuit area.

16. The distributed processing system according to claim 15, wherein
the information about the first process includes an indicator indicating desirability of a result obtained by inputting a result of the first process into a machine learning model, and
the reading includes reading, when a first condition among a plurality of the given conditions that the indicator is less than a first given value is satisfied, the second template for the second circuit logic that executes the second process, from the storage area, the second process including a plurality of processing elements to which at least one of deletion of one or more processing elements, replacement of one or more processing elements, and addition of one or more processing elements, from among a plurality of processing elements included in the first process, has been applied.

17. The distributed processing system according to claim 15, wherein
the information about the first process includes information about a load on the first circuit logic that executes the first process, and
the reading includes reading, when a second condition among a plurality of the given conditions that the information about the load is equal to or greater than a second given value is satisfied, the second template for the second circuit logic with a size larger than a size of the first circuit logic, from the storage area.

18. The distributed processing system according to claim 15, comprising:
a plurality of the control apparatuses; and
a shared storage area shared among the plurality of the control apparatuses,
wherein the processor stores, into the storage area, a selectable template that has not been written into the circuit area during a time period in which the given condition continues to be satisfied, from the shared storage area.

19. The distributed processing system according to claim 18, wherein
the processor moves a third template that is selected based on an unused time period from among the plurality of templates stored in the storage area, to the shared storage area, according to a usage of the storage area.

20. The distributed processing system according to claim 15, wherein
the processor generates a selectable template that has not been written into the circuit area during a time period in which the given condition continues to be satisfied, based on one or more templates stored in the storage area.
